(19) United States
(12) Patent Application Publication
(10) Pub. No.: US 2026/0113984 A1
(43) Pub. Date: Apr. 23, 2026

(54) SEMICONDUCTOR STRUCTURE AND METHOD OF FORMING THEREOF

(71) Applicant: TAIWAN SEMICONDUCTOR MANUFACTURING COMPANY, LTD., Hsinchu (TW)

(72) Inventors: Yu-Lung TUNG, Kaohsiung City (TW); Xiaodong WANG, Hsinchu City (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/919,972

(22) Filed: Oct. 18, 2024

(51) Int. Cl. H01L 29/423; H01L 21/8234; H01L 23/528; H01L 27/088; H01L 29/06; H01L 29/08; H01L 29/66; H01L 29/775; H01L 29/78; H01L 29/786

(52) U.S. Cl. CPC H10D 30/6735; H10D 30/014; H10D 30/43; H10D 30/6757; H10D 62/121; H10D 62/151; H10D 84/013; H10D 84/0149; H10D 84/038; H10W 20/427; H10D 30/024; H10D 30/62; H10D 84/0158; H10D 84/834

(57) ABSTRACT

A method of forming a semiconductor structure includes a number of operations. Source/drain regions are formed on opposite sides of channel regions over a substrate. A gate structure is formed over the channel regions. A plurality of metal line is formed over a front-side of the substrate. A plurality of metallization layers is formed on a backside of the substrate. A backside source/drain contact is formed on a second one of the source/drain regions, wherein the second one of the source/drain regions is free of the front-side source/drain contact.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is schematic view of a wafer including a front-side interconnect structure and a backside interconnect structure on a device region thereof in accordance with some embodiments of the present disclosure.

FIGS. 2A and 2B illustrate a layout diagram of a logic circuit on a front-side and a backside of a semiconductor structure, respectively, according to some embodiments of the present disclosure.

FIGS. 2C, 2D and 2E illustrate cross-sectional views obtained from reference cross-sections C1-C1′, C2-C2′ and C3-C3′ in FIGS. 2A and 2B.

FIGS. 3 through 9C illustrate schematic views of intermediate stages in the formation of a logic circuit on a semiconductor structure in accordance with some embodiments.

FIGS. 10A and 10B illustrate a layout diagram of a logic circuit on a backside and a front-side of a semiconductor structure, respectively, according to some embodiments of the present disclosure.

FIG. 10C illustrates a cross-sectional view obtained from reference cross-sections C1-C1′ in FIGS. 10A and 10B.

FIGS. 11A and 11B illustrate a layout diagram of a logic circuit on a backside and a front-side of a semiconductor structure, respectively, according to some embodiments of the present disclosure.

FIG. 11C illustrates a cross-sectional view obtained from reference cross-sections C1-C1′ in FIGS. 11A and 11B.

FIGS. 12A and 12B illustrate a layout diagram of a logic circuit on a backside and a front-side of a semiconductor structure, respectively, according to some embodiments of the present disclosure.

FIG. 12C illustrates a cross-sectional view obtained from reference cross-sections C1-C1′ in FIGS. 12A and 12B.

FIGS. 13A and 13B illustrate a layout diagram of a logic circuit on a backside and a front-side of a semiconductor structure, respectively, according to some embodiments of the present disclosure.

FIG. 13C illustrates a cross-sectional view obtained from reference cross-sections C1-C1′ in FIGS. 13A and 13B.

FIGS. 14A and 14B illustrate a layout diagram of a logic circuit on a backside and a front-side of a semiconductor structure, respectively, according to some embodiments of the present disclosure.

FIG. 14C illustrates a cross-sectional view obtained from reference cross-sections C1-C1′ in FIGS. 14A and 14B.

FIGS. 15A and 15B illustrate a layout diagram of a logic circuit on a backside and a front-side of a semiconductor structure, respectively, according to some embodiments of the present disclosure.

FIG. 15C illustrates a cross-sectional view obtained from reference cross-sections C1-C1′ in FIGS. 15A and 15B.

FIGS. 16A and 16B illustrate a layout diagram of a logic circuit on a backside and a front-side of a semiconductor structure, respectively, according to some embodiments of the present disclosure.

FIG. 16C illustrates a cross-sectional view obtained from reference cross-sections C1-C1′ in FIGS. 16A and 16B.

FIGS. 17A and 17B illustrate a layout diagram of a logic circuit on a front-side and a backside of a semiconductor structure, respectively, according to some embodiments of the present disclosure.

FIGS. 17C, 17D and 17E illustrate cross-sectional views obtained from reference cross-sections C1-C1′, C2-C2′ and C3-C3′ in FIGS. 17A and 17B.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, in a cell routing of the IC structure, Vdd and Vss power routing may occupy too many routing resources and therefore impact the cell scaling as well as the performance of the IC structure (e.g., RC delay or IR drop). Hence, a part of power lines and power conductive contacts are moved to wafer backside, so as to reduce the routing loading and improve the circuit density in a same chip area. Nevertheless, the power conductive contact on the wafer backside may not be aligned with the source/drain region when forming thereof, which in turn non-overlaps with the source/drain region and/or overlaps with the gate, such that an unwanted connection may occur and therefore impacts the performance of IC structure.

Backside power delivery is proposed to avoid front-side metal interconnect routing congestion and electrical performance loss due to complex signal paths and power delivery networks, which sustains continuous demand of higher integrated circuit density and electrical performance on a semiconductor chip. In some embodiments, front-side metal connections with backside power rails (BSPR) may form backside and front-side parallel power distributions to the same front-side device, and it may mitigate circuit operation speed degradation caused by high resistance along interconnect path from backside power rail to the front-side device. In one or more embodiments of present disclosure, a method of forming a semiconductor structure includes forming front-side circuit cells where the circuits are powered only by backside power rails (BSPR) and the front-side metals for parallel power connection are removed. The formed front-side metal tracks are used only for signal routing, which either reduces chip area by reducing cell height with removal of original front-side power rails or boosts circuit performance by enlarging front-side signal metal width or space.

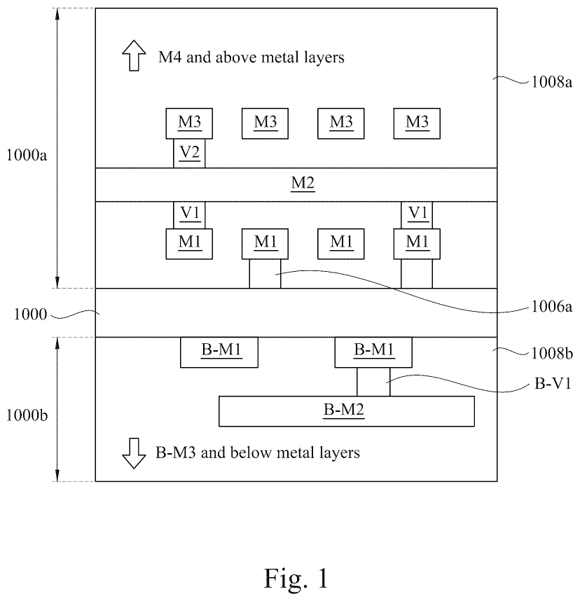

Reference is made to FIG. 1. FIG. 1 is schematic view of a wafer including a front-side interconnect structure and a backside interconnect structure on a device region thereof in accordance with some embodiments of the present disclosure. As shown in FIG. 1, a device region 1000 is provide in the wafer W and includes, such as gate, channel, and source/drain regions. A front-side interconnect structure 1000a is formed after the device region formation. Specifically, the front-side interconnect structure 1000a is formed to have front-side vias 1006a such as front-side gate vias or front-side source/drain vias. The front-side interconnect structure 1000a may further include, for example, metallization layers, labeled as M1, M2, and M3, with two layer of metallization via or interconnect, labeled as V1 and V2. Other embodiments may contain more or fewer metallization layers and more or fewer number of corresponding vias. The metal line illustrated here just for an example, and the metal line may be otherwise oriented (rotated 90 degrees or at other orientations). The front-side interconnect structure 1000a includes a full metallization stack, including a portion of each of metallization layers M1, M2, and M3 connected by the interconnect V1 and V2, with the front-side vias 1006a such as front-side gate vias and the front-side source/drain vias connecting the stack to the gates and the source/drain regions of the transistor in the device region 1000. Also included in the front-side interconnect structure 1000a shown in FIG. 1 is a front-side IMD (inter-metal dielectric) layer 1008a. The front-side IMD layer 1008a may provide electrical insulation as well as structural support for the various features in the front-side interconnect structure 1000a.

As shown in FIG. 1, a backside interconnect structure 1000b is formed after device region formation. The backside interconnect structure 1000b is formed to include, for example, two metallization layers, labeled as B-M1 and B-M2, with one layer of metallization via B-V1 connected between the metallization layers B-M1 and B-M2. Other embodiments may contain more or fewer metallization layers and corresponding more or fewer number of vias. The metal line illustrated here just for an example, and the metal line may be otherwise oriented (rotated 90 degrees or at other orientations). The backside interconnect structure 1000b may include a full metallization stack including the metallization layer and the metallization layer B-M1 connecting the stack to the source/drain region of the transistor in the device region 1000. Also included in the backside interconnect structure 1000b shown in FIG. 1 can be a backside IMD layer 1008b. The backside IMD layer 1008b may provide electrical insulation as well as structural support for the various features in the backside interconnect structure 1000b.

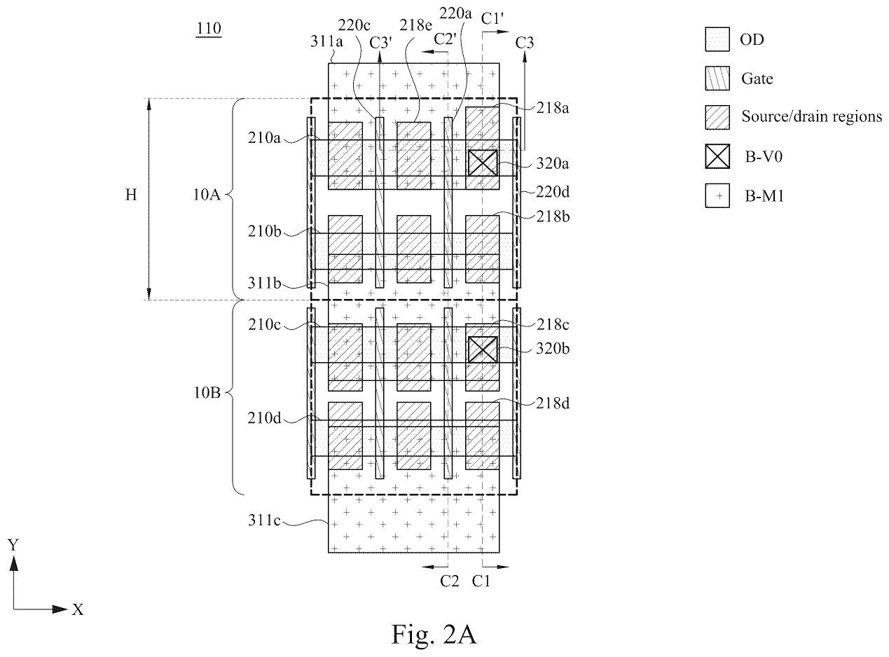

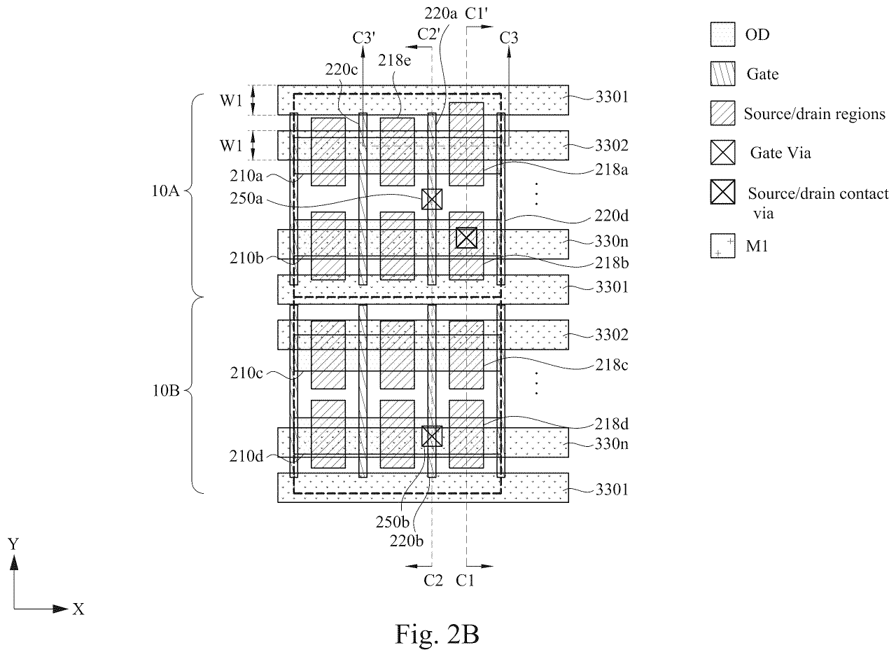

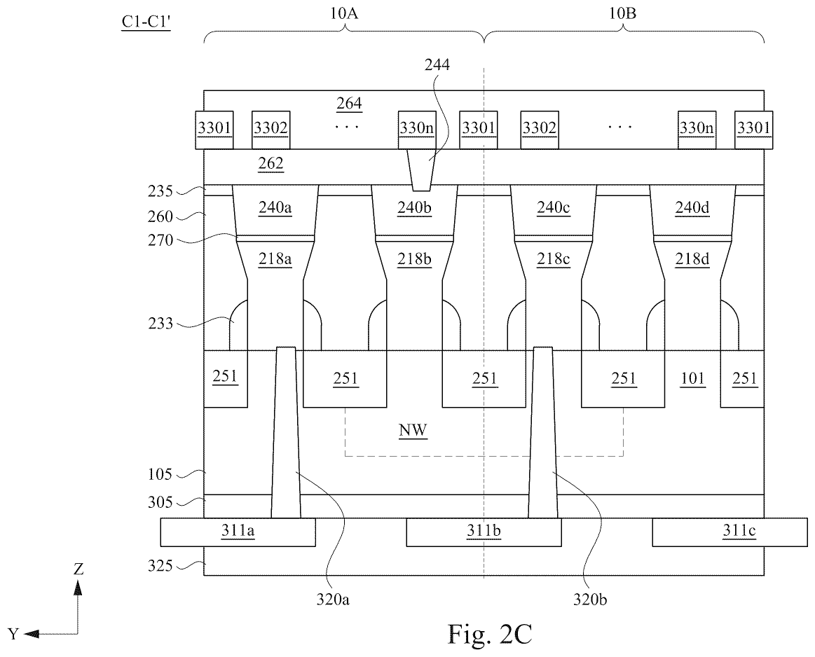

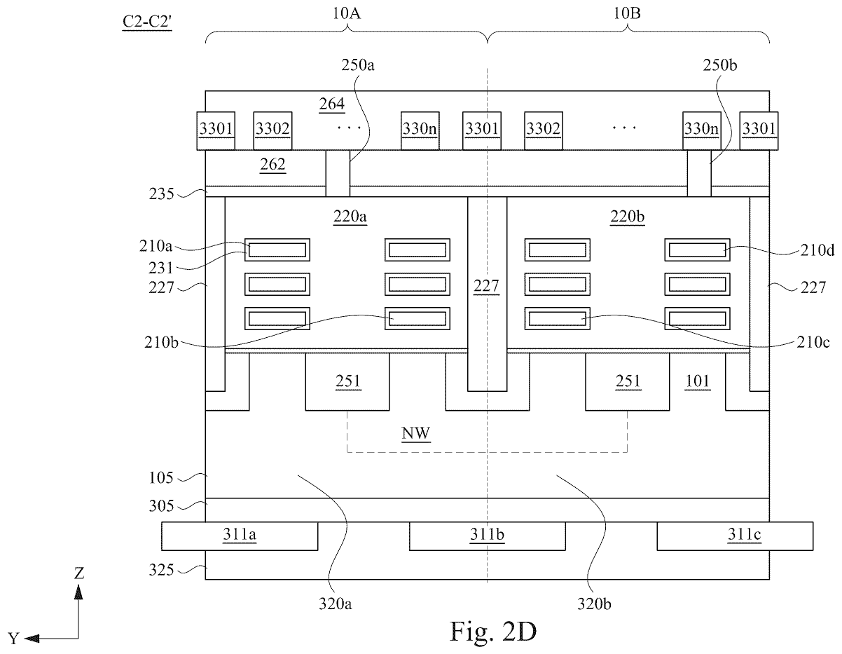

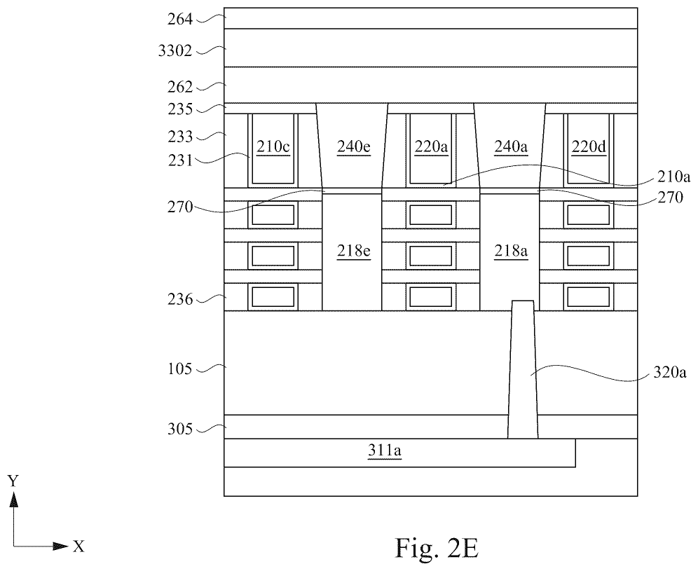

Reference is made to FIGS. 2A-2E. FIGS. 2A and 2B illustrate a layout diagram of a logic circuit 110 on a backside and a front-side of a semiconductor structure, respectively, according to some embodiments of the present disclosure. FIGS. 2C, 2D and 2E illustrate cross-sectional views obtained from reference cross-sections C1-C1′, C2-C2′ and C3-C3′ in FIGS. 2A and 2B.

FIGS. 2A and 2B illustrate a logic circuit 110 including cells 10A and 10B arranged in the same row in a cell. The outer boundary of each of the cells 10A and 10B is illustrated using dashed lines. In some embodiments, the cells 10A and 10B may have the same cell height H1. In FIGS. 2A and 2B, it should be noted that the configuration of the cells 10A and 10B in the logic circuit 110 as illustrated used as an illustration, and not to limit the disclosure. In some embodiments, the row in the cell of the logic circuit 110 may include more logic cells or fewer logic cells than the layout shown in FIGS. 2A and 2B. Each logic cell provides a circuit or portion thereof, exemplary functionality provided by the cells includes, but are not limited to NAND, NOR, AND, XOR, XNOR, SACN, inverter, Flip-Flop, latch, and/or other suitable logic or storage functions.

In some embodiments, the logic circuit 110 may include a plurality of transistors such as NMOSFET transistors or PMOSFET transistors. The silicon channel regions of the NMOSFET and PMOSFET transistors are formed by semiconductor sheets 210a, 210b, 210c and 210d (collectively referred as semiconductor sheets 210). The semiconductor sheets 210 are stacked along the Z-direction (see FIG. 2D) and are wrapped by the gate electrode, and the Z-direction is perpendicular to the plane formed by the X-direction and Y-direction.

As shown in FIGS. 2A and 2B, the logic circuit 110 may include gate electrodes 220a, 220b, 220c and 220d (collectively referred as gate electrodes 220) extending in the Y-direction. The gate electrodes 220 may extend in parallel with each other. In some embodiments, the gate electrode 220 may be portions of gate structure wrapping the semiconductor sheets 210 as the channels of the transistors in the logic circuit 110.

In FIGS. 2A and 2B, the logic circuit 110 may include source/drain regions 218a, 218b, 218c, 218d and 218e (collectively referred as source/drain regions 218) extending in the Y-direction. The source/drain regions 218 may extend in parallel with each other. The source/drain regions 218 may between the gate electrodes 220. On the other hands, the source/drain regions 218a/218b are formed on opposite sides of the semiconductor sheets 210 wrapped around by the gate electrodes 220. The source/drain regions 218 are on opposite sides of the semiconductor sheets 210. The semiconductor sheets 210 as the channel regions, the gate structures including the gate electrodes 220 and the source/drain regions 218 may form the transistors in the logic circuit 110 on the semiconductor structure.

FIG. 2B illustrates the logic circuit 110 on the front-side of the semiconductor structure. On the front-side of the semiconductor structure, the logic circuit 110 may include n numbers of metal lines (i.e., metal lines 3301, 3302, . . . 330n collectively referred as metal lines 330) extending along the X-direction and overlapping each of the cells 10A and 10B. In some embodiments, the lines can be interchangeably referred to metal layers, conductive lines, conductive layers, or conductors. In FIG. 2B, the metal lines 3301, 3302, . . . 330n may have the same width W1. In FIG. 2B, the metal lines 3301 overlap the cell boundary (e.g., the cell boundary of the cells 10A and 10B). The gate electrodes 220 are electrically connected to an overlying level (e.g., front-side metal line M1 level) through gate vias 250a and 250b (collectively referred as gate vias 250). In some embodiments, in the cell 10B, the gate electrode 250b is electrically connected to the metal line 330n overlapping the cell 10B. The source/drain regions 218 are electrically connected to an overlying level (e.g., front-side metal line M1 level) through a source/drain contact via 244. In some embodiments, in the cell 10A, the source/drain region 218 is electrically connected to the metal line 330n through the source/drain contact via 244.

FIG. 2A illustrates the logic circuit 110 on the backside of the semiconductor structure. On the backside of the semiconductor structure, the logic circuit 110 may include metallization layers 311a, 311b and 311c (collectively referred as metallization layers 311) at B-M1 level and backside contacts 320a and 320b (collectively referred as backside contacts 320) connecting the metallization layers 311 and the source/drain regions 218. The metallization layers 311a, 311b and 311c extend along the X-direction and parallel with each other. In some embodiments, the metallization layers can be interchangeably referred to metal lines, conductive lines, conductive layers, or conductors. In FIG. 2A, the metallization layers 311 extend across the cell boundaries, and the source/drain regions 218 may overlap the metallization layers 311. As illustrated in FIG. 2A, the source/drain region 218a can be electrically coupled to the underlying metallization layer 311a through the backside contact 320a. The source/drain region 218c can be electrically coupled to the underlying metallization layer 311b through the backside contact 320b.

In one or more embodiments of the present disclosure, the metallization layers 311 may include a power supply voltage line interchangeably referred to as a Vdd line that is provided with positive a power supply voltage Vdd, and a power supply voltage line interchangeably referred to as a Vss line that is provided with power supply voltage Vss. In some embodiments, the cell can be powered through the positive power supply node Vdd that has a positive power supply voltage (also denoted as VDD). The cell can be also connected to power supply voltage Vss (also denoted as VSS), which may be an electrical ground. In some embodiments, the cell can be powered through the positive power supply node Vdd that has a positive power supply voltage (also denoted as VDD). The cell can be also connected to power supply voltage Vss (also denoted as VSS), which may be an electrical ground. Throughout the description, the notations of metal lines may be followed by the metal line levels they are in, wherein the respective metal line level is placed in parenthesis. The metallization layers 311 of the logic circuit 110 on the backside of the semiconductor structure may be used as backside power rails (BSPRs) for the logic circuit 110.

In one or more embodiments of the present disclosure, the metal lines 330 of the logic circuit 110 on the front-side of the semiconductor structure may be used for signal routing and not for power, and the logic circuit 110 is powered only by the metallization layers 311 of the logic circuit 110 on the backside of the semiconductor structure, so as to reduce cell height occupied by front-side power rail in the chip area and/or boost circuit performance. It should be noted that the configuration of the cells 10A and 10B in the logic circuit 110 as illustrated used as an illustration, and not to limit the disclosure. For illustration, the front-side gate vias 250a and 250b, the front-side source/drain via 244 and the backside contacts 320a and 320b near the reference cross-sections C1-C1′, C2-C2′ and C3-C3′ are illustrated. In some embodiments, numbers of front-side vias and backside contacts may be provided to connect the source/drain regions 218 and the gate electrodes 220 to the metallization layers 311 or the metal lines 330.

Reference is made to FIGS. 2A, 2B and 2D. FIG. 2D illustrates a cross-sectional views obtained from reference cross-sections C2-C2′ in FIGS. 2A and 2B. In FIG. 2D, n-type well regions NW is formed over a semiconductor substrate 105. The n-type well region NW is formed across the boundary (illustrated using dash line) of the cells 10A and 10B in the X-direction. A plurality of fin strips 101 is semiconductor strip patterned in the substrate 105. The semiconductor sheets 210b and 210c are formed over the n-type well region NW and arranged in the Z-direction. In some embodiments, the portions of the semiconductor substrate 105 out of the n-type well regions NW may be a p-type well region. The semiconductor sheets 210a and 210d are formed over portions of the semiconductor substrate 105 out of the n-type well region NW.

A plurality of fin strips 101 is semiconductor strip patterned in the substrate 105. A shallow trench isolation (STI) structure 251 can be formed over the substrate 105 and laterally surround the fin strip 101. In some embodiments, the top surface of the STI structure 251 is coplanar with a top surface of the fin strip 101. In some embodiments, the top surface of the STI structure 251 is above or below the top surface of the fin strip 101. In some embodiments, the STI structure 251 may separate the features of adjacent devices. A plurality of shallow trench isolation (STI) structures 251 is formed between the semiconductor sheets 210a and 210b.

The semiconductor sheets 210 including the semiconductor sheets 210a and 210b may be regarded as channel layers 210 stacked along the Z-direction over the fin strip 101 and acting as active regions. A plurality of gate dielectric layers 231 are formed over the fin strips 101 and wrap around the semiconductor sheets 210a and 210b. In the cell 10A, a transistor is formed by the semiconductor sheets 210a are wrapped by the gate electrode 220a with the gate dielectric layers 231, and a transistor is formed by the semiconductor sheets 210b are wrapped by the gate electrode 220a with the gate dielectric layers 231. In the cell 10B, a transistor is formed by the semiconductor sheets 210c are wrapped by the gate electrode 220b with the gate dielectric layers 231, and a transistor is formed by the semiconductor sheets 210d are wrapped by the gate electrode 220b with the gate dielectric layers 231.

In some embodiments, each dielectric region 227 is a gate-cut structure for the gate structure, and the gate-cut structure is formed by a cut metal gate (CMG) process. In some embodiments, the dielectric region 227 may be made of dielectric material. In some embodiments, the dielectric regions 227 may be formed of or comprise SiO₂, SiOC, SiOCN, or the like, or combinations thereof. In some embodiments, the dielectric regions 227 may be made of a nitride-based material, such as Si₃N₄, or a carbon-based material, such as SiOCN, or combinations thereof. In some embodiments, the dielectric regions 227 may be made of a metal oxide material. In some embodiments, the dielectric regions 227 may be made of a material having a dielectric constant greater than about 9 (e.g., high dielectric constant (high-k) material). For example, the dielectric regions 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. In some embodiments, the dielectric regions 227 may include dielectric liners, which may be formed of, for example, silicon oxide.

In some embodiments, hard mask layers 235 are formed over the gate electrode 220a and 220b. In some embodiments, the hard mask layer 235 can be interchangeably referred to a gate top dielectric. In some embodiments, the hard mask layer 235 is made of a different material than the dielectric region 227. In some embodiments, the hard mask layer 235 may be made of dielectric material, such as SiO₂, Si₃N₄, SiON, SiOC, SiOCN base dielectric material, or combinations thereof.

In FIG. 2D, an inter-layer dielectric (ILD) layer 262 is formed over the hard mask layers 235. An inter-metal dielectric (IMD) layer 264 is formed over the ILD layer 262 and can provide electrical insulation as well as structural support for the various features therein, such as the metal lines 330 including metal lines 3301-330n. In some embodiments, the ILD layer 262 and/or the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

The gate vias 250a and 250b are formed to pass through the ILD layer 262 and the hard mask layer 235 and respectively land on the gate electrodes 220a and 220b. In some embodiments, the gate vias 250a and 250b may include a metal-containing material such as titanium nitride, titanium oxide, tungsten, cobalt, ruthenium, aluminum, copper, combinations thereof, multi-layers thereof, or the like. As illustrated in FIG. 2D, the gate via 250a is formed to pass through the ILD layer 262 and the hard mask layer 235 and land on the gate electrode 220a in the cell 10A, and the gate via 250b is formed to pass through the ILD layer 262 and the hard mask layer 235 and land on the gate electrode 220b in the cell 10B.

As illustrated in FIG. 2D, an ILD layer 305 is formed over a backside to the semiconductor substrate 105. An inter-metal dielectric (IMD) layer 325 is formed over the ILD layer 305 and can provide electrical insulation as well as structural support for the various features therein, such as the metallization layers 311 including the metallization layers 311a, 311b and 311c. In some embodiments, the ILD layer 262 and/or the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In the cross-sectional view as illustrated in FIG. 2D, the gate electrodes 220a and 220b are disconnected to the metallization layers 311a, 311b and 311c.

Reference is made to FIGS. 2A, 2B and 2C. FIG. 2C illustrates a cross-sectional views obtained from reference cross-sections C1-C1′ in FIGS. 2A and 2B.

As illustrated in FIGS. 2A, 2B and 2C, the source/drain regions 218 including the source/drain regions 218a, 218b, 218c and 218d are formed between gate spacers 233 over the STI regions 251. The source/drain region 218b is formed over the semiconductor sheets 210b over the n-type well region NW, and the source/drain region 218c is formed over the semiconductor sheets 210c over the n-type well region NW. The source/drain region 218a is formed over the semiconductor sheets 210a out of the n-type well region NW. The source/drain region 218d is formed over the semiconductor sheets 210d out of the n-type well region NW. In some embodiments, a dopant in the source/drain regions 218b and 218c over the n-type well regions NW has an opposite conductivity type to another dopant in the source/drain regions 218a and 218d out of the n-type well region NW. The source/drain regions 218b and 218c may have a p-type dopant. In some embodiments, the portions of the semiconductor substrate 105 out of the n-type well regions NW may be a p-type well region. The source/drain regions 218a and 218d out of the n-type well region NW may have an n-type dopant.

In some embodiments, the n-type source/drain regions 218a and 218d may include SiP, SiC, SiPC, SiAs, Si, or a combination thereof. In some embodiments, the n-type source/drain regions 218a and 218d may have a phosphorus concentration within a range from about 2E19/cm³ to about 3E21/cm³. In some embodiments, the p-type source/drain regions 218b and 218c may include boron, BF₂, SiGe, or a combination thereof. In some embodiments, the p-type source/drain regions 218b and 218c may have a boron concentration within a range from about 1E19/cm³ to about 6E20/cm³. In some embodiments, the p-type source/drain regions 218b and 218c may have a Ge atomic percentage within a range of about 36% to about 85%. In some embodiments, the p-type source/drain regions 218b and 218c having the p-type dopant may include a carbon-containing material.

An inter-layer dielectric (ILD) layer 260 can be formed over the epitaxial source/drain regions 218 and the gate spacers 233. Acceptable dielectric materials may include phospho-silicate glass (PSG), boro-silicate glass (BSG), boron-doped phospho-silicate glass (BPSG), undoped silicate glass (USG), or the like. In some embodiments, the ILD layers 260 may be made of an oxide, nitride, the like, or combinations thereof. Other insulation materials formed by any acceptable process may be used. In some embodiments, a contact etch stop layer (CESL) is formed between the ILD layer 260 and the epitaxial source/drain regions 218, and gate spacers 233. The CESL may be formed of a dielectric material, such as silicon nitride, silicon oxide, silicon oxynitride, or the like, having a high etching selectivity from the etching of the ILD 260. In some embodiments, a hard mask layer 235 is formed over the ILD layer 260 and the ILD layer 262 is formed over the hard mask layer 235.

As illustrated in FIG. 2C, source/drain contacts 240a, 240b, 240c and 240d (collectively referred as source/drain contacts 240) are respectively formed over the source/drain regions 218a, 218b, 218c and 218d. In FIG. 2C, top surfaces of the source/drain contacts 240a, 240b, 240c and 240d are level with the hard mask layers 235. The ILD layer 262 is formed over the top surfaces of the source/drain contacts 240a, 240b, 240c and 240d. The source/drain contacts 240a, 240b, 240c and 240d may include suitable conductive material. In some embodiments, as illustrated in FIG. 2C, silicide regions 270 may be formed between each of the source/drain regions 218a, 218b, 218c and 218d and the corresponding one of the source/drain contacts 240a, 240b, 240c and 240d for Rc reduction. In some embodiments, the source/drain contacts 240 may be electrically coupled to the metal lines 330 through a source/drain contact vias 244. In FIG. 2C, the metal line 330n is electrically coupled to the source/drain contacts 240 through the contact via 244.

As illustrated in FIGS. 2A and 2C, the backside contact 320 extends from the metallization layer 311a through the ILD layer 305 and the semiconductor substrate 105 to the source/drain region 218a. The backside contacts 320a and 320b may include suitable conductive material. The backside contact 320b extends from the metallization layer 311b through the ILD layer 305 and the semiconductor substrate 105 to the source/drain region 218c. In FIG. 2C, the backside contact 320b passes through the n-type well region NW. In some embodiments, the backside contacts 320a and 320b extend through the fin strips 101.

Reference is made to FIGS. 2A, 2B and 2E. FIG. 2E illustrates a cross-sectional views obtained from reference cross-sections C3-C3′ in FIGS. 2A and 2B.

As illustrated in FIG. 2E, the gate electrode 220a over the gate dielectric layer 231 is between the gate spacers 233. The gate electrode 220a wraps around the semiconductor sheets 210a to form transistors with the source/drain regions 218a and 218e on opposite sides of the semiconductor sheets 210b surrounded by the gate electrode 220a. Inner spacers 236 are on opposite sides of the gate electrode 220a, 220c and 220d between the semiconductor sheets 210a. The silicide regions 270 are between the source/drain contacts 240a, 240e and the source/drain regions 218a, 218e. In FIG. 2E, the gate electrode 220a is between gate electrodes 220c and 220d. The hard mask layer 235 is formed over the gate electrodes 220a, 220c and 220d and the gate spacers 233. The ILD layer 262 is over the hard mask layer 235 and the source/drain contacts 240a and 240e. The metal line 330b is within the IMD layer 264 over the ILD layer 262. The ILD layer 305 is over the backside of the semiconductor substrate 105. The metallization layer 311a is within the backside IMD layer 325 below the ILD layer 305. As illustrated in FIGS. 2B, 2C and 2E, the metal line 330b within the IMD layer 264 is disconnected to the source/drain contacts 218a and 218e, and the metallization layer 311a is electrically connected to the source/drain region 218a through the backside contact 320.

In some embodiments, the metal lines 330 of the logic circuit 110 on the front-side of the semiconductor structure may be used for signal routing and not for power, and the logic circuit 110 is powered only by the metallization layers 311 of the logic circuit 110 on the backside of the semiconductor structure. As illustrated in FIGS. 2A through 2E, in one or more embodiments of the present disclosure, each of the source/drain regions 218 including the source/drain regions 218a, 218b, 218c, 218d and 218e is connected to at most one of the metal lines 330 of the logic circuit 110 on the front-side of the semiconductor structure and the metallization layers 311 of the logic circuit 110 on the backside of the semiconductor structure. As illustrated in FIG. 2C, the source/drain region 218 connected to the front-side source/drain contact via 244 (e.g., the source/drain region 218b) is free of the backside source/drain contacts 320, and the source/drain region 218 connected to the back-side source/drain contacts 320a or 320b (e.g., the source/drain regions 218a and 218c) is free of the front-side source/drain contact via 244. An entirety of a front-side of the source/drain region 218b is covered by the ILD layer 262. Therefore, it either reduces cell height occupied by front-side power rail in the chip area or boosts circuit performance by enlarging front-side signal metal width/space.

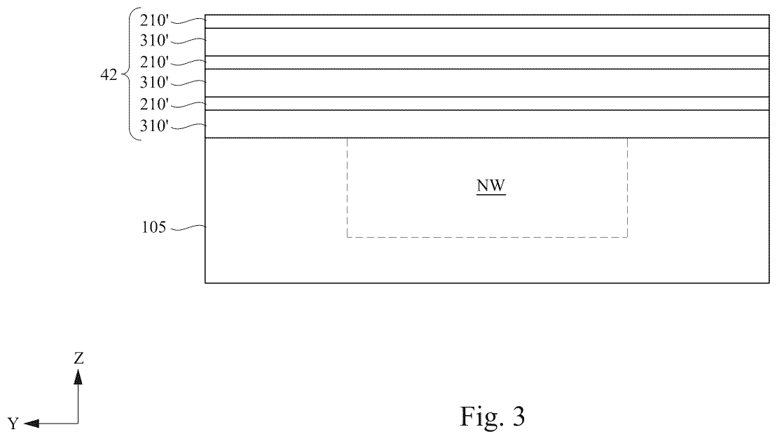

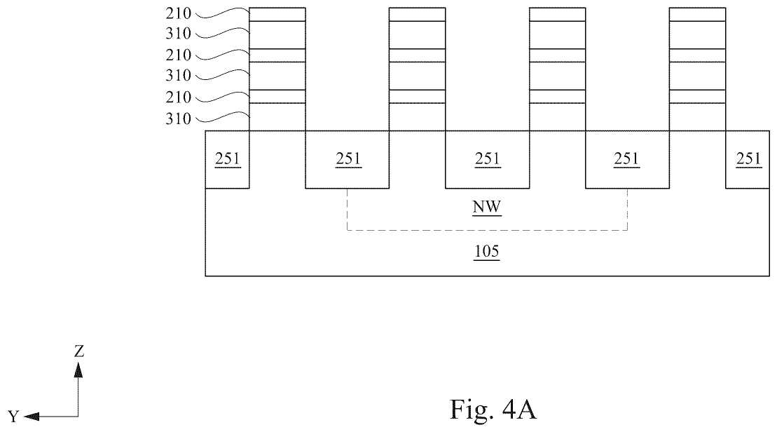

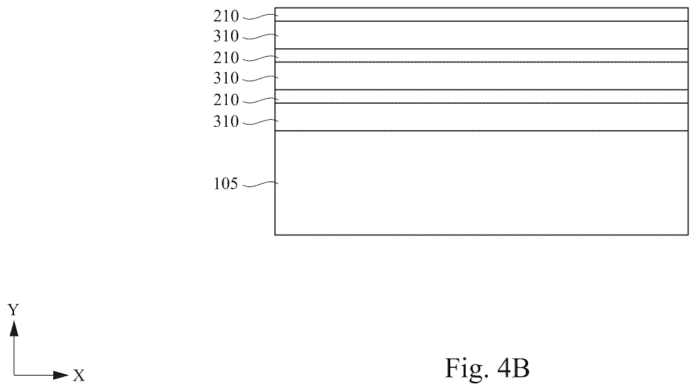

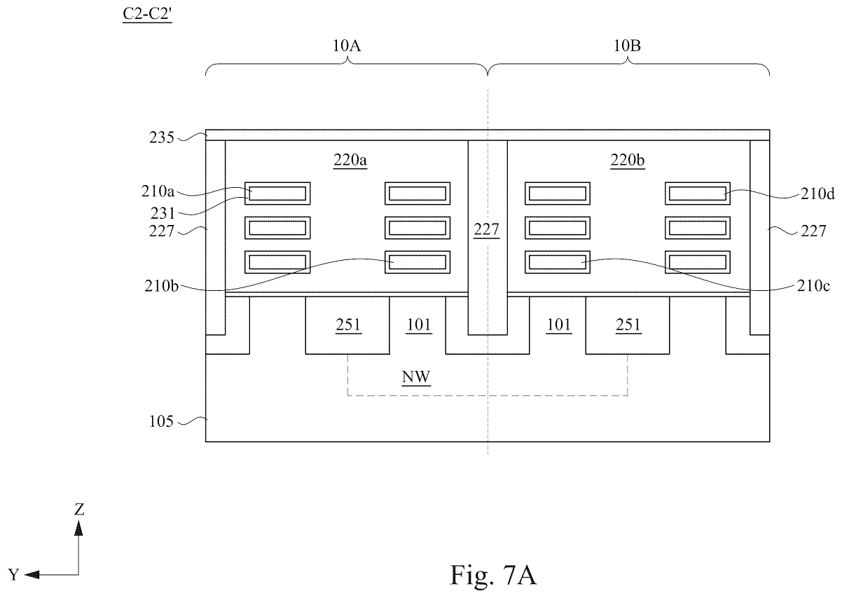

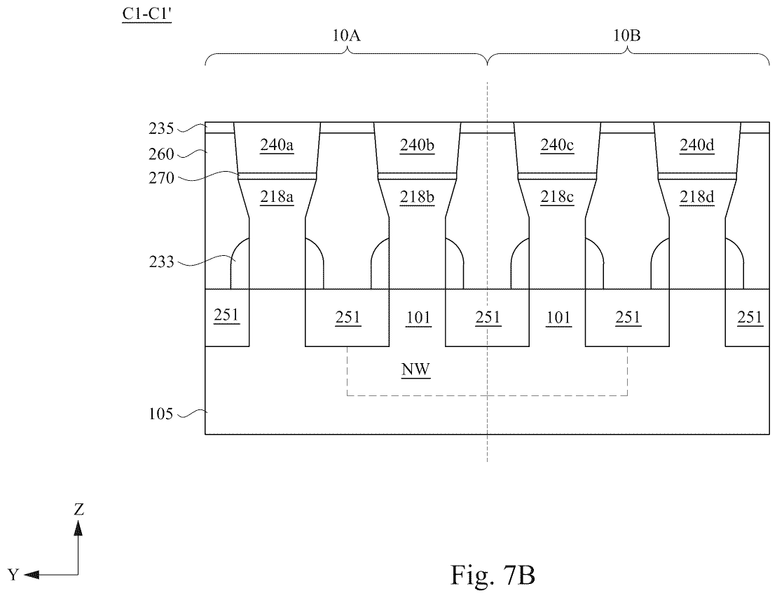

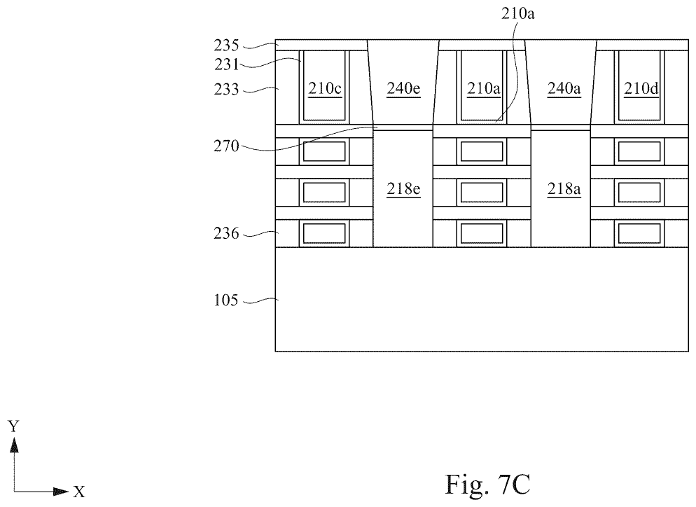

Reference is made to FIGS. 3 through 9C. FIGS. 3 through 9C illustrate schematic views of intermediate stages in the formation of a logic circuit 110 on a semiconductor structure in accordance with some embodiments. FIGS. 3, 4A, 7A, 8A and 9A illustrate cross-sectional views of intermediate stages obtained from the reference cross-section C2-C2′ of the top view as illustrated in FIGS. 2A and 2B in the formation of the semiconductor structure in accordance with some embodiments. FIGS. 7B, 8B and 9B illustrate cross-sectional views of intermediate stages obtained from the reference cross-section C1-C1′ of the top view as illustrated in FIGS. 2A and 2B in the formation of the semiconductor structure in accordance with some embodiments. FIGS. 4B, 5, 6, 7C, 8C and 9C illustrate cross-sectional views of intermediate stages obtained from the reference cross-section C3-C3′ of the top view as illustrated in FIGS. 2A and 2B in the formation of the semiconductor structure in accordance with some embodiments.

As with the other method embodiments and exemplary devices discussed herein, it is understood that parts of the semiconductor structure 100 may be fabricated by a complementary metal-oxide-semiconductor CMOS technology process flow, and thus some processes are only briefly described herein. Further, the exemplary integrated circuit structure 100 may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary semiconductor structure 100 includes a plurality of semiconductor devices (e.g., transistors), including PFETs, NFETs, etc., which may be interconnected. It is understood that additional operations can be provided before, during, and after the processes shown by FIGS. 3 through 9C, and some of the operations described below can be replaced or eliminated, for additional embodiments of the method. The order of the operations/processes may be interchangeable.

Reference is made to FIG. 3. A substrate 105 is provided for forming nano-FETs. The substrate 105 may be a semiconductor substrate, such as a bulk semiconductor, a semiconductor-on-insulator (SOI) substrate, or the like, which may be doped (e.g., with a p-type or an n-type impurity) or undoped. The substrate 105 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the substrate 105 may be a material, such as a III-V compound semiconductor, a II-VI compound semiconductor, or the like. In some embodiments, the semiconductor material of the substrate 105 may include silicon; germanium; a compound semiconductor including silicon carbide, gallium arsenide, gallium stannum, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

By way of example and not limitation, the substrate 105 may be lightly doped with a p-type or an n-type impurity to form n-type well regions and p-type well regions having an opposite conductivity type to the n-type well regions. In FIG. 3, an n-type well region NW is formed over the substrate 105, and portions of the substrate 105 out of the n-type well region NW may be p-type well regions in some embodiments. In some embodiments, an anti-punch-through (APT) implantation may be performed on an upper portion of the substrate 105 to form an APT region. During the APT implantation, impurities may be implanted in the substrate 105. The impurities may have a conductivity type opposite from a conductivity type of source/drain regions that will be subsequently formed in each of the n-type region and the p-type region. The APT region may extend under the source/drain regions in the nano-FETs. The APT region may be used to reduce the leakage from the source/drain regions to the substrate 105. In some embodiments, the doping concentration in the APT region may be in the range of about 10¹⁸ cm⁻³ to about 10¹⁹ cm⁻³. In some embodiments, the n-type well region NW can have p-type devices, such as PMOS transistors, formed thereon, and the p-type well region (i.e., the portions of the substrate 105 out of the n-type well region NW) can have n-type devices, such as NMOS transistors, formed thereon.

As illustrated in FIG. 3, a multi-layer stack 42 is formed over the substrate 105. The multi-layer stack 42 can include alternating first semiconductor layers 310′ and second semiconductor layers 210′. The first semiconductor layers 310′ formed of a first semiconductor material, and the second semiconductor layers 210′ are formed of a second semiconductor material different than the first semiconductor material. The semiconductor materials may each be selected from the candidate semiconductor materials of the substrate 105. In some embodiments, the multi-layer stack 42 includes two layers of each of the first semiconductor layers 310 and the second semiconductor layers 210′. It should be appreciated that the multi-layer stack 42 may include any number of the first semiconductor layers 310′ and the second semiconductor layers 210′.

In some embodiments, and as will be subsequently described in greater detail, the first semiconductor layers 310′ will be removed and the second semiconductor layers 210′ will patterned to form channel layers for the nano-FETs. The first semiconductor layers 310′ can be sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers in the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) may be formed to be thinner than other layers (e.g., the first semiconductor layers 310′).

Reference is made to FIGS. 4A and 4B. Trenches can be patterned in the substrate 105 and the multi-layer stack 42 to form fin strips 101, semiconductor sheets 310, and semiconductor sheets 210. The semiconductor sheets 210 may be used as channel layers 210. The semiconductor sheets 310 and the channel layers 210 include the remaining portions of the first semiconductor layers 310′ and the second semiconductor layers 210′, respectively. The trenches may be patterned by any acceptable etch process, such as a reactive ion etch (RIE), neutral beam etch (NBE), the like, or a combination thereof. The etching may be anisotropic. The fin strips 101, the semiconductor sheets 310, and the channel layers 210 may be patterned by any suitable method. For example, the fin strips 101, the semiconductor sheets 310, and the channel layers 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

The STI structures 251 can be formed over the substrate 105 and between adjacent fin strips 101. The STI structures 251 are disposed around at least a portion of the fin strips 101 such that at least a portion of the semiconductor sheet 310 and the channel layer 210 protrude from between adjacent STI structures 251. In some embodiments, the top surfaces of the STI structures 251 are coplanar (within process variations) with the top surfaces of the fin strips 101. The STI structures 251 may be formed by any suitable method. For example, an insulation material can be formed over the substrate 105 and the semiconductor sheets 310 and the channel layers 210, and between adjacent fin strips 101. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In some embodiments, the insulation material is formed such that excess insulation material covers the semiconductor sheets 310 and the channel layers 210. Although the STI structures 251 are each illustrated as a single layer, some embodiments may utilize multiple layers. For example, in some embodiments a liner (not separately illustrated) may first be formed along surfaces of the substrate 105, the fin strips 101, the semiconductor sheets 310, and the channel layers 210. Thereafter, a fill material, such as those previously described may be formed over the liner.

A removal process is then applied to the insulation material to remove excess insulation material over the semiconductor sheets 310 and the channel layers 210. In some embodiments, a planarization process such as a chemical mechanical polish (CMP), an etch-back process, combinations thereof, or the like may be utilized. In embodiments in which a mask remains on the semiconductor sheets 310 and the channel layers 210, the planarization process may expose the mask or remove the mask. After the planarization process, the top surfaces of the insulation material and the mask (if present) or the semiconductor sheet 310/the channel layer 210 are coplanar (within process variations). Accordingly, the top surfaces of the mask (if present) or the semiconductor sheet 310/channel layer 210 can be exposed through the insulation material. In some embodiments, no mask remains on the semiconductor sheets 310 and the channel layers 210. The insulation material is then recessed to form the STI structures 251. The insulation material is recessed, such as in a range from about 30 nm to about 80 nm, such that at least a portion of the semiconductor sheets 310 and the channel layers 210 can protrude from between adjacent portions of the insulation material. Further, the top surfaces of the STI structures 251 may have a flat surface as illustrated, a convex surface, a concave surface (such as dishing), or a combination thereof. The insulation material may be recessed using any acceptable etching process, such as one that is selective to the material of the insulation material (e.g., selectively etches the insulation material of the STI structures 251 at a faster rate than the materials of the fin strips 101 and the semiconductor sheets 310 and the channel layers 210). For example, an oxide removal may be performed using dilute hydrofluoric (dHF) acid.

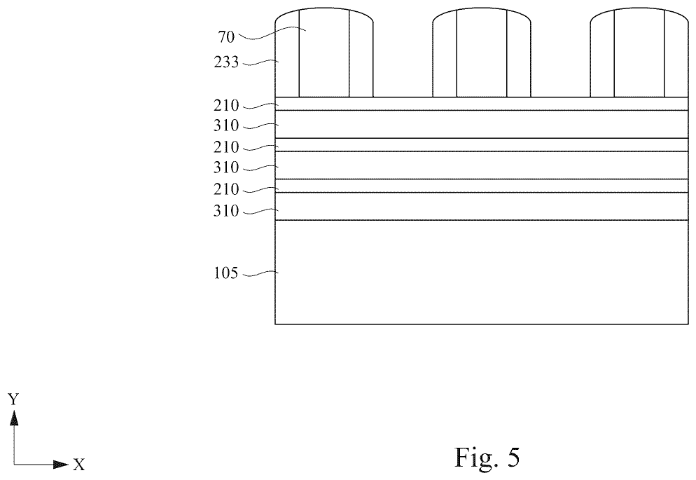

Reference is made to FIG. 5. A plurality of dummy gate structures 70 is formed on the fin strips 101, the semiconductor sheets 310, and the channel layers 210. In some embodiments, forming the dummy gate structures 70 may include a dummy dielectric layer, a dummy gate layer, and a mask layer are sequentially formed on the fin strips 101, the semiconductor sheets 310, and the channel layers 210.

In some embodiments, the dummy dielectric layer of the dummy gate structures 70 may be formed of a dielectric material such as silicon oxide, silicon nitride, a combination thereof, or the like, which may be deposited or thermally grown according to acceptable techniques.

Subsequently, a dummy gate layer of the dummy gate structures 70 is formed over the dummy dielectric layer. Subsequently, a mask layer is formed over the dummy gate layer. The dummy gate layer of the dummy gate structures 70 may be deposited over the dummy dielectric layer and then planarized, such as by a CMP. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer.

The mask layer of the dummy gate structures 70 may be deposited over the dummy gate layer. The mask layer may be formed of a dielectric material such as silicon nitride, silicon oxynitride, or the like. The mask layer is patterned using acceptable photolithography and etching techniques to form masks. The pattern of the masks is then transferred to the dummy gate layer and the dummy dielectric layer by any acceptable etching technique to form dummy gates. The pattern of the masks may optionally be further transferred to the dummy dielectric layer by any acceptable etching technique to form dummy dielectrics.

As illustrated in FIG. 5, the dummy gate structures 70 cover portions of the semiconductor sheets 310 and the channel layers 210 that will be exposed in subsequent processing to form active regions. The dummy gates may also have lengthwise directions substantially perpendicular (within process variations) to the lengthwise directions of the fin strips 101. The masks can optionally be removed after patterning, such as by any acceptable etching technique.

The layers 233 serving as gate spacers can be formed over the semiconductor sheets 310 and the channel layers 210 and on exposed sidewalls of the dummy gate structure. In some embodiments, the layer 233 can be interchangeably referred to top spacers or upper gate spacers. In some embodiments, the layer 233 may include multiple dielectric material and selected from a group consist of SiO₂, Si₃N₄, carbon doped oxide, nitrogen doped oxide, porous oxide, air gap, or combinations thereof. The layer 233 may be formed by conformally depositing one or more dielectric material(s) and subsequently etching the dielectric material(s). Acceptable dielectric materials may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gate structure 70 (thus forming the layer 233).

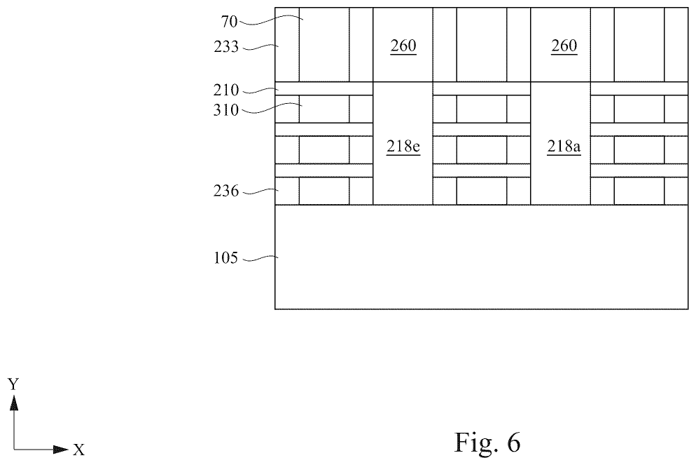

Reference is made to FIG. 6. Source/drain recesses can be formed in the semiconductor sheets 310 and the channel layers 210. In some embodiments, the source/drain recesses extend through the semiconductor sheets 310 and the channel layers 210 and into the fin strips 101. In some embodiments, the fin strips 101 may be etched such that bottom surfaces of the source/drain recesses 94 are disposed below the top surfaces of the STI structures 251. The source/drain recesses may be formed by etching the semiconductor sheets 310 and the channel layers 210 using an anisotropic etching processes, such as a RIE, a NBE, or the like. The layers 233 and the dummy gate structures 70 act as mask portions of the fin strips 101, the semiconductor sheets 310, and the channel layers 210 during the etching processes used to form the source/drain recesses. A single etch process may be used to etch each of the semiconductor sheets 310 and the channel layers 210, or multiple etch processes may be used to etch the semiconductor sheets 310 and the channel layers 210. Timed etch processes may be used to stop the etching of the source/drain recesses after the source/drain recesses reach a desired depth.

Subsequently, inner spacers 236 are formed on sidewalls of the remaining portions of the semiconductor sheets 310, e.g., those sidewalls exposed by the source/drain recesses. As will be subsequently described in greater detail, source/drain regions will be subsequently formed in the source/drain recesses, and the semiconductor sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the semiconductor sheets 310.

As an example to form the inner spacers 236, the source/drain recesses can be laterally expanded. Specifically, portions of the sidewalls of the semiconductor sheets 310 exposed by the source/drain recesses 94 may be recessed. Although sidewalls of the semiconductor sheets 310 are illustrated as being straight, the sidewalls may be concave or convex. The sidewalls may be recessed by any acceptable etching process, such as one that is selective to the material of the semiconductor sheets 310 (e.g., selectively etches the material of the semiconductor sheets 310 at a faster rate than the material of the channel layers 210). The etching may be isotropic. For example, when the channel layers 210 are formed of silicon and the semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the semiconductor sheets 310.

The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the layer 233. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the layer 233, the outer sidewalls of the inner spacers 236 may extend beyond or be recessed from the sidewalls of the layer 233. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

Epitaxial source/drain regions 218 including source/drain regions 218a and 218e can be formed in the source/drain recesses, such that each dummy gate structure 70 (and corresponding channel layers) is disposed between respective adjacent pairs of the epitaxial source/drain regions 218. In some embodiments, the gate spacers 233 and the inner spacers 236 are used to separate the epitaxial source/drain regions 218 from, respectively, the dummy gate structures 70 and the semiconductor sheets 310 by an appropriate lateral distance so that the epitaxial source/drain regions 218 do not short out with subsequently formed gates of the resulting nano-FETs.

The source/drain regions 218 may include p-type source/drain regions 218b and 218c over the n-type well region NW and n-type source/drain regions 218a and 218d over the p-type well region (i.e., portions of the substrate 105 out of the n-type well region NW). In some embodiments, the n-type source/drain regions 218a and 218d may include SiP, SiC, SiPC, SiAs, Si, or a combination thereof. In some embodiments, the n-type source/drain regions 218a and 218d may have a phosphorus concentration within a range from about 2E19/cm³ to about 3E21/cm³. In some embodiments, the p-type source/drain regions 218b and 218c may include boron, BF₂, SiGe, or a combination thereof. In some embodiments, the p-type source/drain regions 218a may have a boron concentration within a range from about 1E19/cm³ to about 6E20/cm³. In some embodiments, the p-type source/drain regions 218b and 218c may have a Ge atomic percentage within a range of about 36% to about 85%. In some embodiments, 218b and 218c having the p-type dopant may include a carbon-containing material.

In FIG. 6, an inter-layer dielectric (ILD) layer 260 can be deposited over the epitaxial source/drain regions 218 and the gate spacers 233, and the dummy gate structure 70. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. In some embodiments, the ILD layers 260 and 262 may be made of an oxide, nitride, the like, or combinations thereof. Other insulation materials formed by any acceptable process may be used. In some embodiments, a contact etch stop layer (CESL) is formed between the ILD layer 260 and the epitaxial source/drain regions 218, the gate spacers 233, and the dummy gate structure 70. The CESL may be formed of a dielectric material, such as silicon nitride, silicon oxide, silicon oxynitride, or the like, having a high etching selectivity from the etching of the ILD 260. The CESL may be formed by any suitable method, such as CVD, ALD, or the like.

Subsequently, a removal process is performed to level the top surfaces of the ILD layer 260 with the top surfaces of the dummy gate structure 70. In some embodiments, a planarization process such as a chemical mechanical polish (CMP), an etch-back process, combinations thereof, or the like may be utilized. After the planarization process, the top surfaces of the gate spacers 233, the ILD layer 260, the CESL, and the dummy gate structure 70 are coplanar (within process variations). Accordingly, the top surfaces of the dummy gate structure 70 can be exposed through the ILD layer 260. In some embodiments, the dummy gate structures 70 remain, and the planarization process levels the top surface of the ILD layer 260 with the top surfaces of the dummy gate structures 70.

Reference is made to FIGS. 7A, 7B and 7C. The dummy gate structures 70 are removed in an etching process, so that recesses 126 are formed. In some embodiments, the dummy gate structures 70 are removed by an anisotropic dry etch process. For example, the etching process may include a dry etch process using reaction gas(es) that selectively etch the dummy gate structures 70 at a faster rate than the ILD layer 260 and the gate spacers 233. Each recess can expose and/or overlies portions of the channel layers 210 disposed between adjacent pairs of the epitaxial source/drain regions 218.

The remaining portions of the semiconductor sheets 310 are then removed to expand the recesses, such that openings are formed in regions between the channel layers 210. The remaining portions of the semiconductor sheets 310 can be removed by any acceptable etching process that selectively etches the material of the semiconductor sheets 310 at a faster rate than the material of the channel layers 210. The etching may be isotropic. For example, when the semiconductor sheets 310 are formed of silicon germanium and the channel layers 210 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the channel layers 210. In some embodiments, the removing of the remaining portions of the semiconductor sheets 310 can be interchangeably referred to as a channel releasing process. The channel layers 210 can be interchangeably referred to as a vertically stacked multiple channels (sheets) and may have a vertically sheet pitch within a range of from about 10 nm to about 30 nm. In some embodiments, the channel layers 210 may have a thickness within a range from about 4 nm to about 10 nm. In some embodiments, the vertically sheet pitch of the between adjacent two of the channel layers 210 may be within a range from about 6 to about 20 nm.

Gate dielectric layers 231 are formed in the recesses exposing the channel layers 210. Gate electrodes 220 are formed over the gate dielectric layers 231. The gate electrodes may include gate electrodes 220a, 220b, 220c and 220d. The gate dielectric layers 231 and the gate electrodes 220 form replacement gate structures wrap around the channel layers 210, and each wrap around all (e.g., four) sides of the second channel layer 210. Specifically, the gate dielectric layer 231 is disposed on the sidewalls and/or the top surfaces of the fin strips 101; on the top surfaces, the sidewalls, and the bottom surfaces of the channel layers 210; and on the sidewalls of the gate spacers 233. Subsequently, the gate electrodes 220 are formed over the gate dielectric layer 231.

In some embodiments, the gate dielectric layers 231 can be formed over top surfaces of the fin strip 101 and along top surfaces, sidewalls, and bottom surfaces of the channel regions 210. The gate electrodes 220 including gate electrodes 220a, 220b, 220c and 220d are formed over the gate dielectric layer 231. In some embodiments, the gate electrodes 220 may be made of conductive material, such as aluminum (Al), copper (Cu), tungsten (W), titanium (Ti), tantalum (Ta), or other applicable materials. In some embodiments, the gate electrode 220 may include multiple material structure selected from a group consisting of poly gate/SiON structure, metals/high-K dielectric structure, Al/refractory metals/high-K dielectric structure, silicide/high-K dielectric structure, or combination. In some embodiments, the gate electrodes 220 may include one or more work-function layers (not shown). In some embodiments, the work function layer can be made of metal material, and the metal material may include N-work-function metal or P-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal may include titanium nitride (TiN), tungsten nitride (WN), tantalum nitride (TaN), ruthenium (Ru) or a combination thereof. In some embodiments, the gate electrode 220 is formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

In some embodiments, the gate dielectric layers 231 can be made of silicon oxide (SiOₓ), silicon nitride (SiₓN_{y}), silicon oxynitride (SiON), dielectric material(s) with high dielectric constant (high-k), or a combination thereof. The high dielectric constant (high-k) material may be hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. In some embodiments, the gate dielectric layer 231 includes Lanthanum (La) dopant. In some embodiments, the gate dielectric layer 231 can be deposited by a plasma enhanced chemical vapor deposition (PECVD) process or by a spin coating process.

The dielectric region 227 can be formed as a gate-cut structure for the gate structure. In some embodiments, the dielectric regions 227 can be formed by a cut metal gate (CMG) process. Specifically, portions of the gate electrodes 220 and the gate dielectric layers 231 are removed to reappear portions of the gate trenches with the gate spacers 233 as their sidewalls. The portions of the gate electrodes 220 and the gate dielectric layer 231 may be removed by dry etching, wet etching, or a combination of dry and wet etching. For example, a wet etching process may include exposure to a hydroxide containing solution (e.g., ammonium hydroxide), deionized water, and/or other suitable etchant solutions. Subsequently, a dielectric material is deposited into the gate trenches, followed by a planarization process to remove excess portions of the dielectric material. The remaining dielectric material forms the dielectric regions 227. In some embodiment, a top surface of the dielectric region 227 can be level with a top surface of the gate electrode 220. In some embodiments, the deposition of the dielectric material of the dielectric regions 227 is performed using a conformal deposition process such as ALD, which may be PEALD, thermal ALD, or the like. In some embodiments, material of the dielectric regions 227 is substantially the same as that shown in FIG. 2D, and the related detailed descriptions may refer to the foregoing paragraphs, and are not described again herein for the purpose of simplicity and clarity.

An etch back process is performed on the gate electrodes 220 and the gate spacer 233 to form the hard mask layer 235. Specifically, the etch back process may include a bias plasma etching step. The bias plasma etching step may be performed to remove portions of the gate electrode 220 and the gate spacer 233. Portions of the gate trenches may reappear with shallower depth. Top surfaces of the gate electrode 220 and the gate spacer 233 may be not level with the ILD layer 260. In some embodiments, the bias plasma etching step may use a gas mixture of Cl₂, O₂, BCl₃, and Ar with a bias in a range from about 25V to about 1200V.

In some embodiments, the hard mask layer 235 is formed over the gate electrode 220 and the gate spacer 233 using, for example, a deposition process to deposit a dielectric material over the substrate 105, followed by a CMP process to remove excess dielectric material above the ILD layer 260. The hard mask layer 235 has different etch selectivity than the ILD layer 260, so as to selective etch back the hard mask layer 235 rather than the ILD layer 260. By way of example, if the hard mask layer 235 is made of silicon nitride, the ILD layer 260 may be made of a dielectric material different from silicon nitride. If the hard mask layer 235 is made of silicon carbide (SiC), the ILD layer 260 may be made of a dielectric material different from silicon carbide. Therefore, the hard mask layer 235 can be used to define self-aligned gate contact region and thus referred to as a self-aligned contact (SAC) structure or a SAC layer. In some embodiments, the hard mask layer 235 may have a thickness in a range from about 2 nm to about 60 nm, such as about 2, 5, 10, 15, 20, 25, 30, 35, 40, 45, 50, 55, or 60 nm. In some embodiments, material of the hard mask layer 235 is substantially the same as that shown in FIGS. 2C through 2E, and the related detailed descriptions may refer to the foregoing paragraphs, and are not described again herein for the purpose of simplicity and clarity.

Source/drain contacts 240 formed subsequently are formed in the ILD layer 260 by a self-aligned contact process using the hard mask layer 235 as a contact etch protection layer. The source/drain contacts 240 may include 240a, 240b, 240c, 240d and 240e. In some embodiments, as illustrated in FIGS. 7B and 7C, source/drain silicide regions 270 may be formed on a top of the source/drain regions 218 such as the source/drain regions 218a, 218b, 218c, 218d and 218e. In some embodiments, bottoms of the source/drain regions 218 can be in contact with the well region.

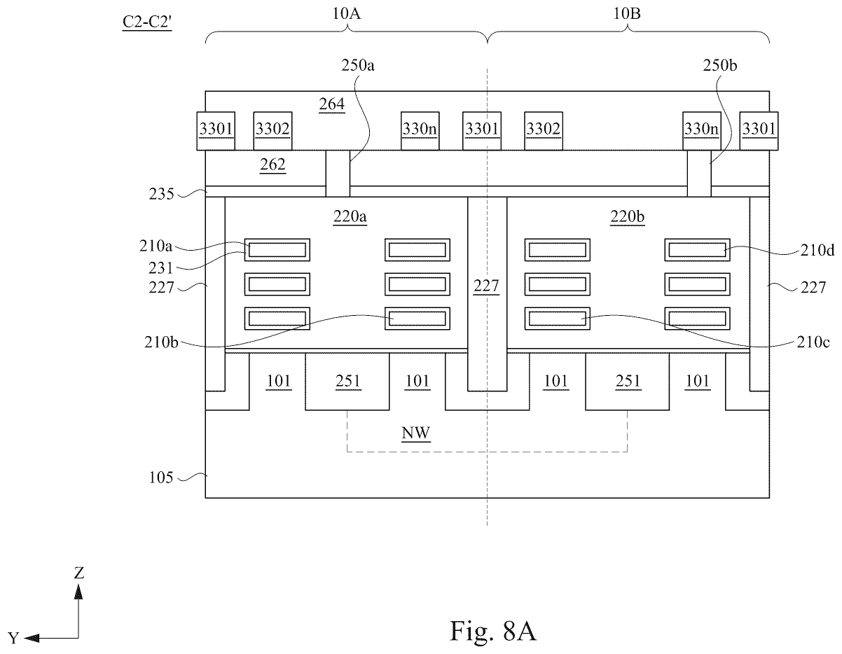

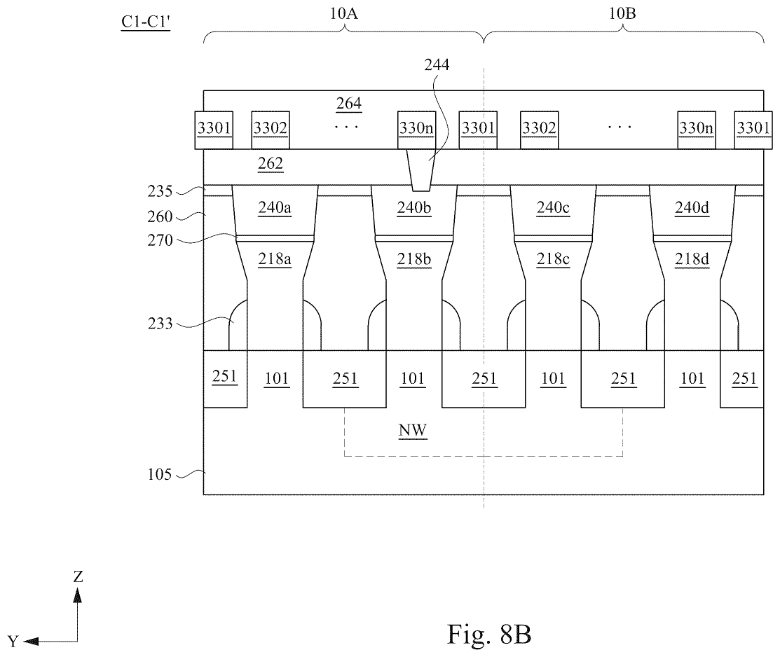

In some embodiments, as illustrated in FIG. 8C, the source/drain contacts 240 are formed so that most of the ILD layers 260 between the gate spacers 233 are removed. The remaining portions of the ILD layers 260 may extend between the source/drain regions 218, as illustrated in FIG. 7B.

Reference is made to FIGS. 8A through 8C. An ILD layer 262 may be deposited over the hard mask layers 235 and the source/drain contacts 240. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, a source/drain contact via 244 is formed in the ILD layer 262 and land on the source/drain contacts 240. Gate vias 250 including gate vias 250a and 250b are formed to pass through the ILD layer 262 and the hard mask layer 235 and land on the gate electrodes 220. In FIG. 8A, the gate via 250a may connect the gate electrode 220a to one of the metal lines 3301-330n in the cell 10A (not illustrated), and the gate via 250b connects the gate electrode 220b to the metal line 330n in the cell 10B. In FIG. 8B, the source/drain contact via 244 connects the source/drain contact 240b to the metal line 330n in the cell 10A. In some embodiments, the gate via 250a and 250b and the source/drain contact via 244 may include a metal-containing material such as titanium nitride, titanium oxide, tungsten, cobalt, ruthenium, aluminum, copper, combinations thereof, multi-layers thereof, or the like.

Subsequently, an interconnect structure including metal lines 330 and vias including gate vias 250 and source/drain contact via 244 can be formed over the ILD layer 262 to electrically connect to the corresponding gate vias 250 or the corresponding source/drain contact vias 244. As shown in FIGS. 8A and 8B, for each of the cells 10A and 10B, the metal lines 330 includes n numbers of the metal lines 3301-330n.

In some embodiments, materials of the metal lines 3301-330n and vias may be made of a conductive material, such as Cu, Co, Ru, Pt, Al, W, Ti, TaN, TiN, or any combinations thereof. Also included in the interconnect structure is an inter-metal dielectric (IMD) layer 264. The IMD layer 264 may provide electrical insulation as well as structural support for the various features of the interconnect structure. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 264 may be made of an oxide, nitride, the like, or combinations thereof.

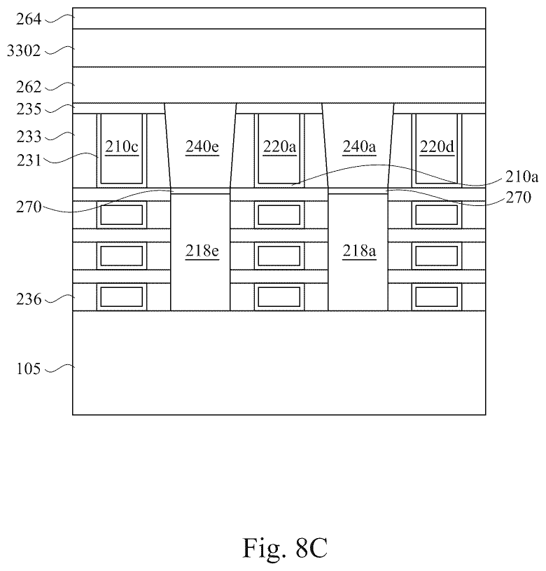

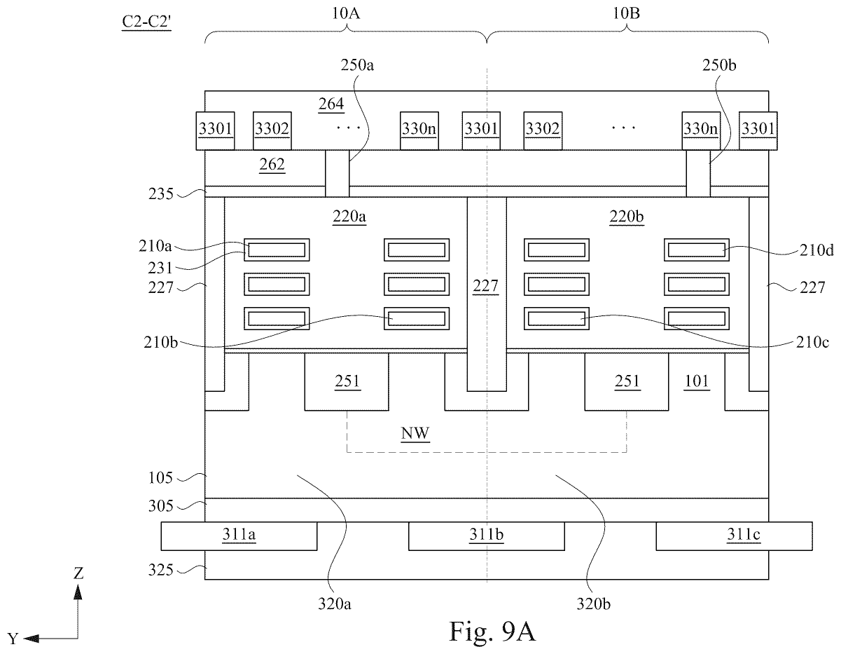

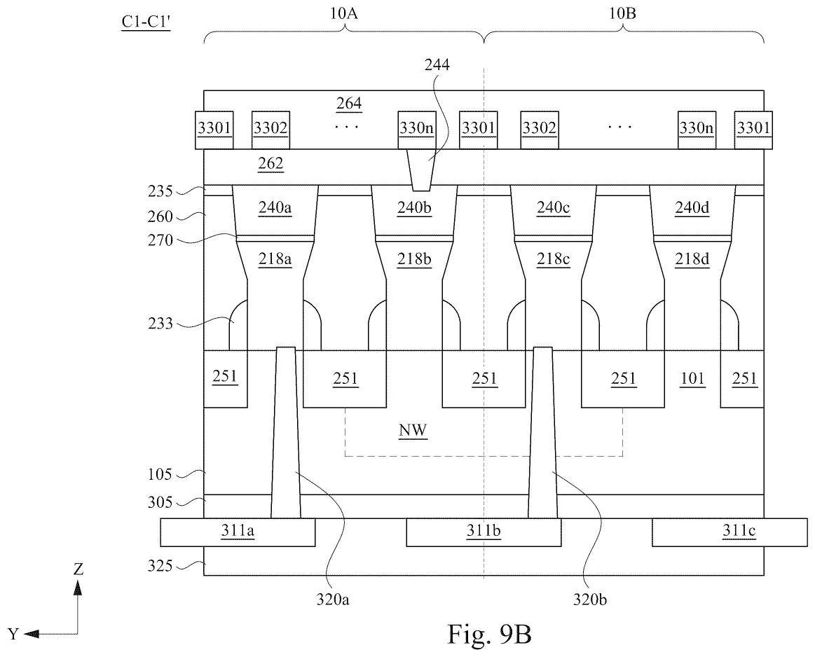

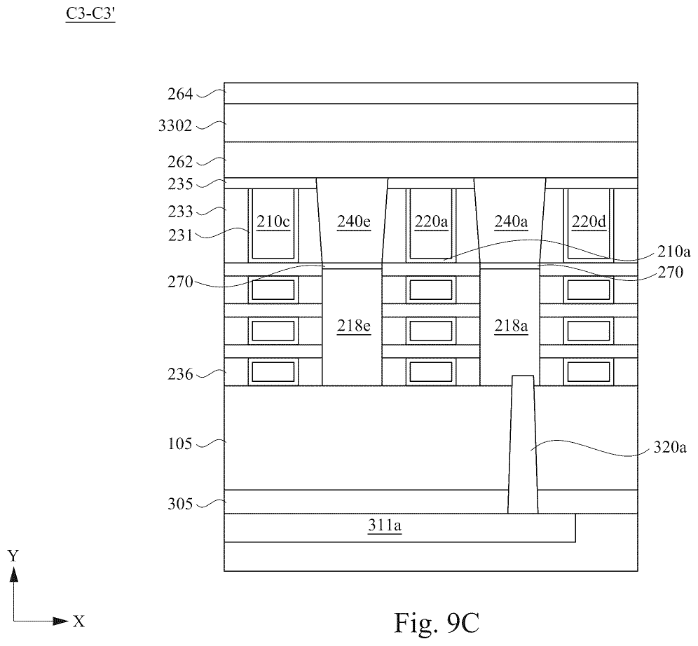

Reference is made to FIGS. 9A, 9B and 9C. After the structure as illustrated in FIGS. 8A through 8C is formed, the structure as illustrated in FIGS. 8A through 8C may be “flipped” upside down so that the backside of the substrate 105 faces up. In some embodiments, portions of the substrate 105 may be removed to thin the substrate 105 by, for example, CMP etching from the backside of the substrate 105. A backside ILD layer 305 may be deposited over the backside of the substrate 105. In some embodiments, the ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, backside contacts 320a and 320b may be formed in the ILD layer 305 and respectively aligned with the source/drain regions 218a and 218c. In some embodiments, the backside contacts 320a and 320b may include a metal-containing material such as titanium nitride, titanium oxide, tungsten, cobalt, ruthenium, aluminum, copper, combinations thereof, multi-layers thereof, or the like.

A backside interconnect structure including metallization layers 311a, 311b and 311c can then be formed over the ILD layer 305 to electrically connect to the corresponding backside contacts 320a and 320b. As shown in FIGS. 9A through 9C, the backside contact 320a connects the metallization layer 311a and the source/drain region 218a, and the backside contact 320b connects the metallization layer 311c and the source/drain region 218c. In some embodiments, materials of the metallization layers 311a, 311b and 311c may be made of a conductive material, such as Cu, Co, Ru, Pt, Al, W, Ti, TaN, TiN, or any combinations thereof. Also included in the interconnect structure is an inter-metal dielectric (IMD) layer 325. The IMD layer 325 may provide electrical insulation as well as structural support for the various features of the interconnect structure. In some embodiments, the IMD layer 325 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 325 may be made of an oxide, nitride, the like, or combinations thereof. After the forming of the backside interconnect structure, the substrate 105 may be “flipped” upside down again so that the backside of the substrate 105 faces down, and the structure as illustrated in FIGS. 9A through 9C is formed.

As an example to form the conductive lines in front-side interconnect structure or backside interconnect structure, trenches/openings for the conductive lines are formed through the IMD layer. The trenches/openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the IMD layer. The remaining liner and conductive material form the conductive lines in the trenches/openings. The conductive lines may be formed in distinct processes, or may be formed in the same process. In some embodiments, material and manufacturing method of the conductive lines (not shown) in other metallization layers are substantially the same as those of the conductive line in the first metallization layer as described above, and the related detailed descriptions may refer to the foregoing paragraphs, and are not described again herein for the purpose of simplicity and clarity and does not in itself dictate a relationship between the various embodiments and/or configurations discussed.

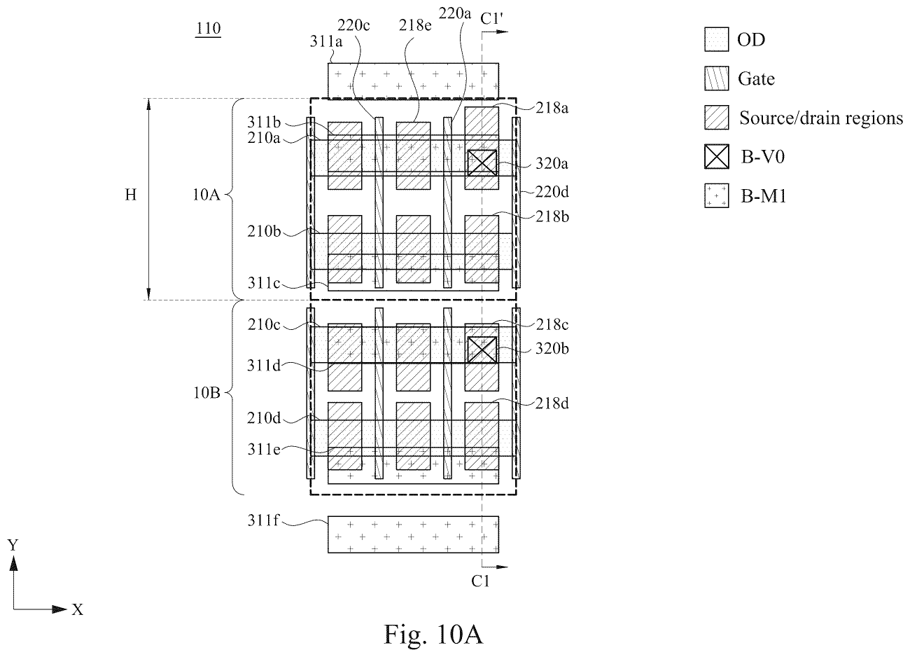

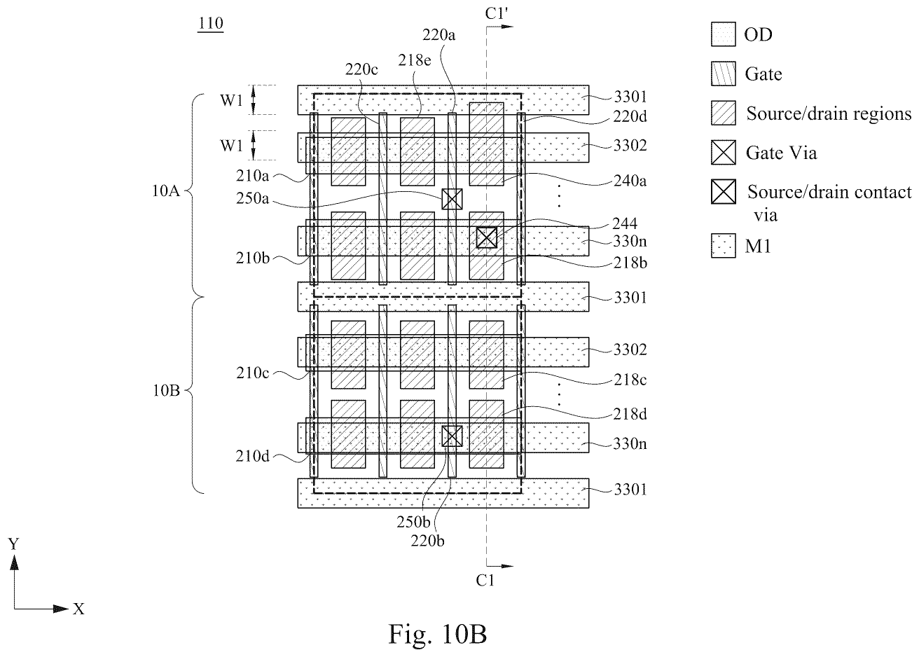

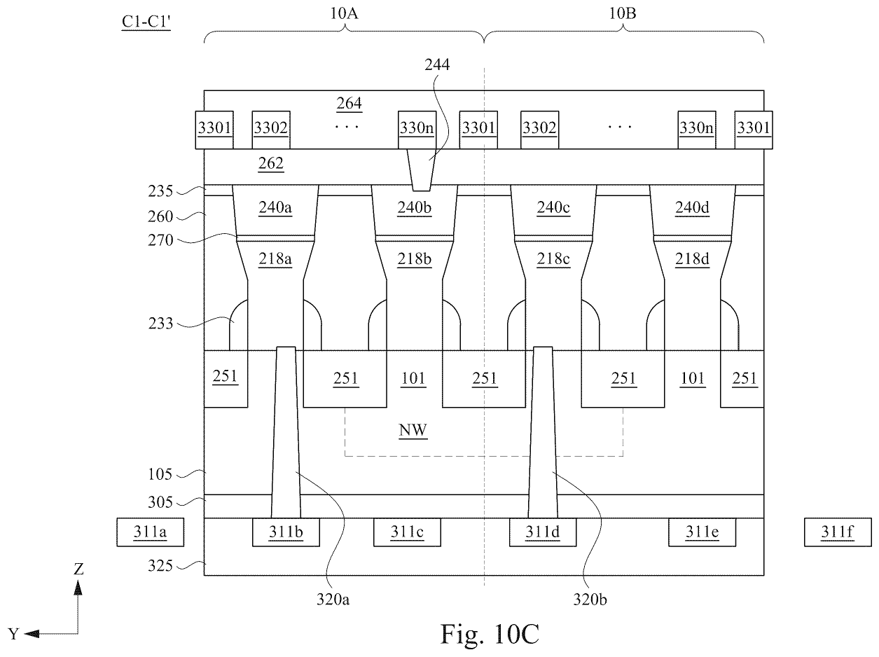

Reference is made to FIGS. 10A through 10C. FIGS. 10A and 10B illustrate a layout diagram of a logic circuit 110 on a backside and a front-side of a semiconductor structure, respectively, according to some embodiments of the present disclosure. FIG. 10C illustrates a cross-sectional view obtained from reference cross-sections C1-C1′ in FIGS. 10A and 10B.

A difference between the structure as illustrated in FIGS. 2A through 2E and the structure as illustrated in FIGS. 10A through 10C includes in FIGS. 10A and 10C more numbers of backside metallization layers 311a, 311b, 311c, 311d, 311e and 311f are provided in the adjacent cells 10A and 10B. In some embodiments, the metallization layers 311a, 311b, 311c, 311d, 311e and 311f of the logic circuit 110 on the backside of the semiconductor structure may have the same power. The width of each of the metallization layers 311a, 311b, 311c, 311d, 311e and 311f is reduced so that the cell 10A may overlap entireties of the metallization layers 311b and 311c and the cell 10B may overlap entireties of the metallization layers 311d and 311e.

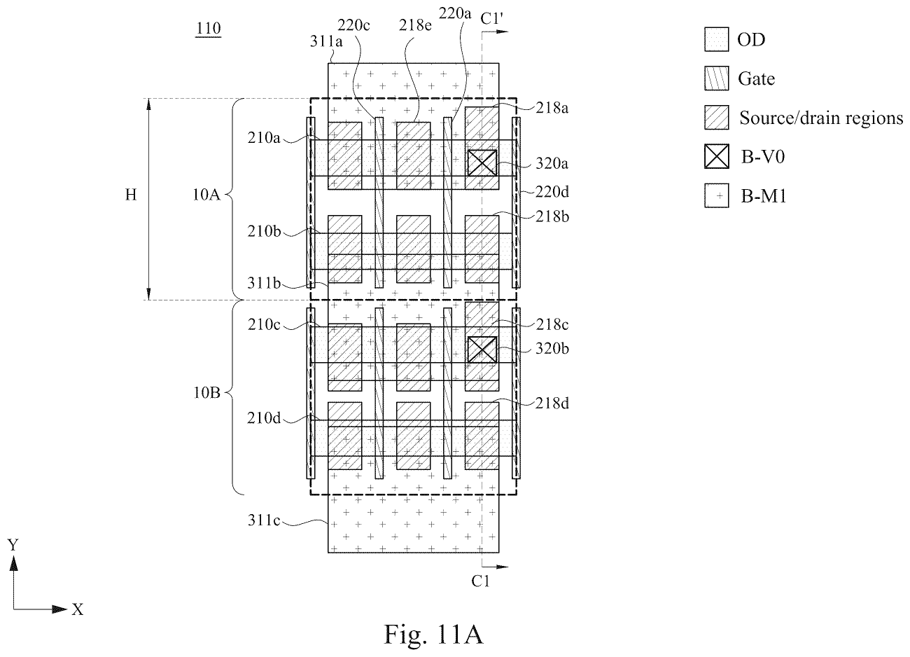

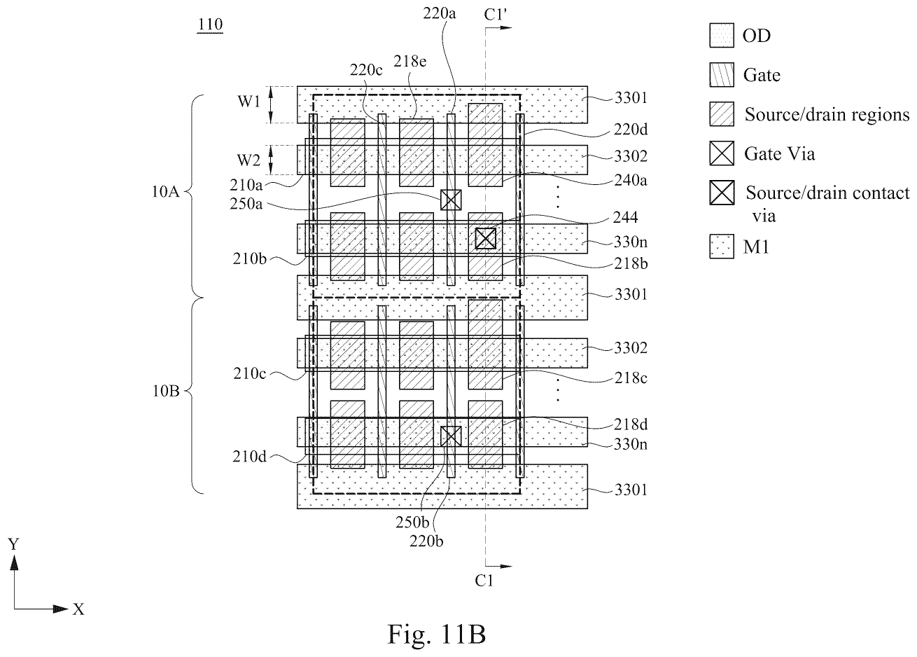

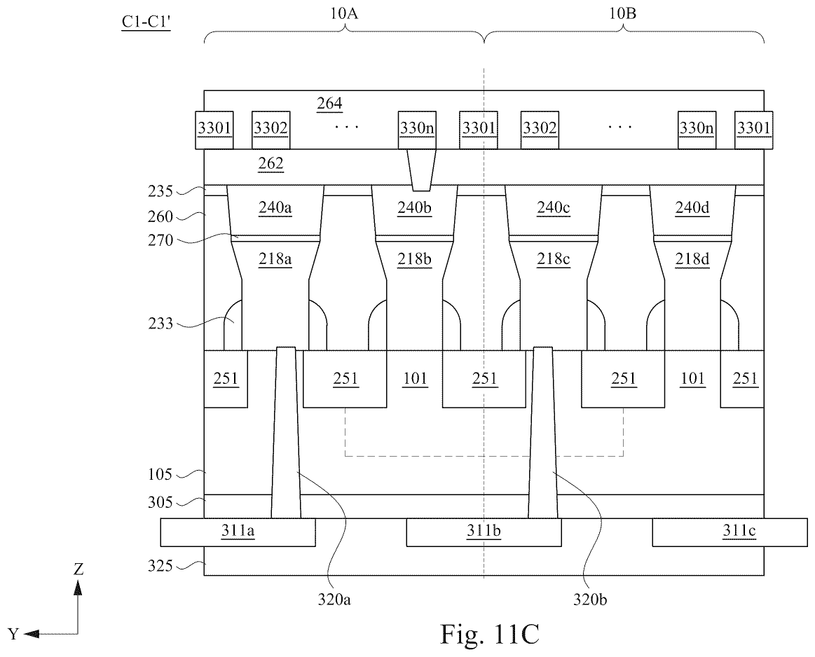

Reference is made to FIGS. 11A through 11C. FIGS. 11A and 11B illustrate a layout diagram of a logic circuit 110 on a backside and a front-side of a semiconductor structure, respectively, according to some embodiments of the present disclosure. FIG. 11C illustrates a cross-sectional view obtained from reference cross-sections C1-C1′ in FIGS. 11A and 11B.

A difference between the structure as illustrated in FIGS. 2A through 2E and the structure as illustrated in FIGS. 11A through 11C includes in FIGS. 11A and 11C the front-side metal lines 330 may have different widths. For example, as illustrated in FIG. 11B, in the cell 10A the metal line 3301 has a width W1, the metal line 3302 has a width W2, and the width W2 of the metal line 3302 is less than the width W1 of the metal line 3301.

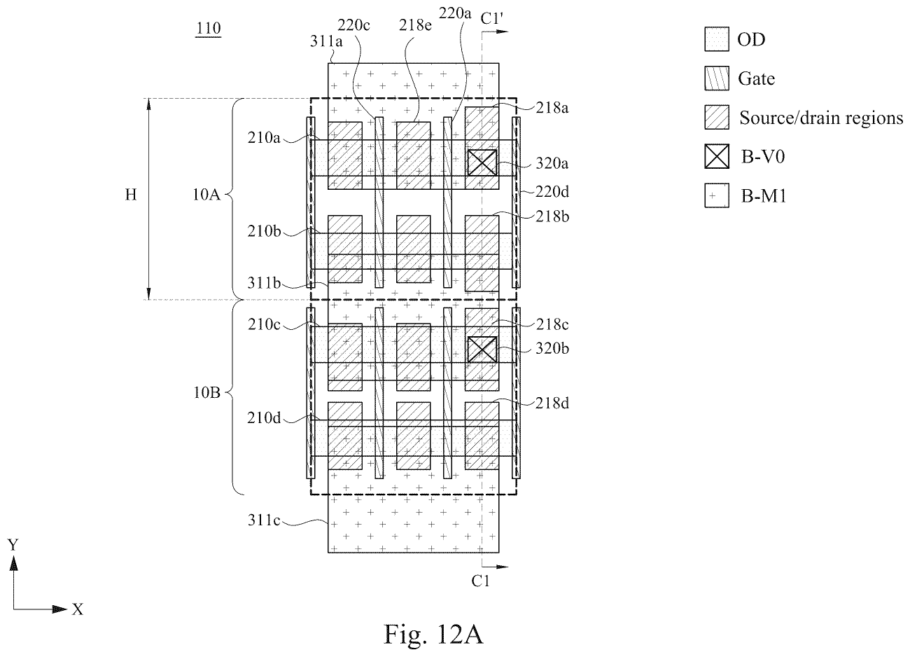

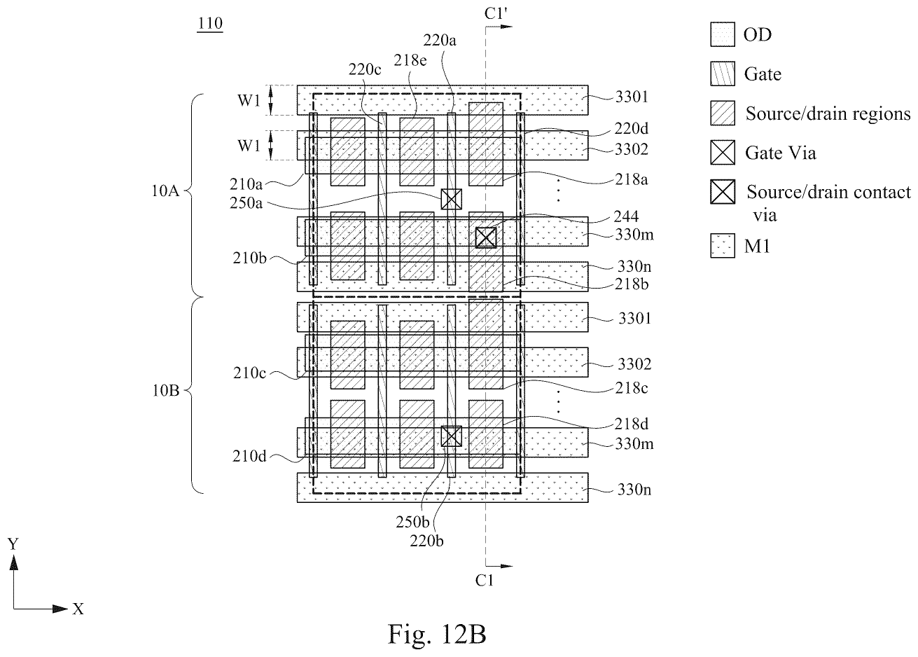

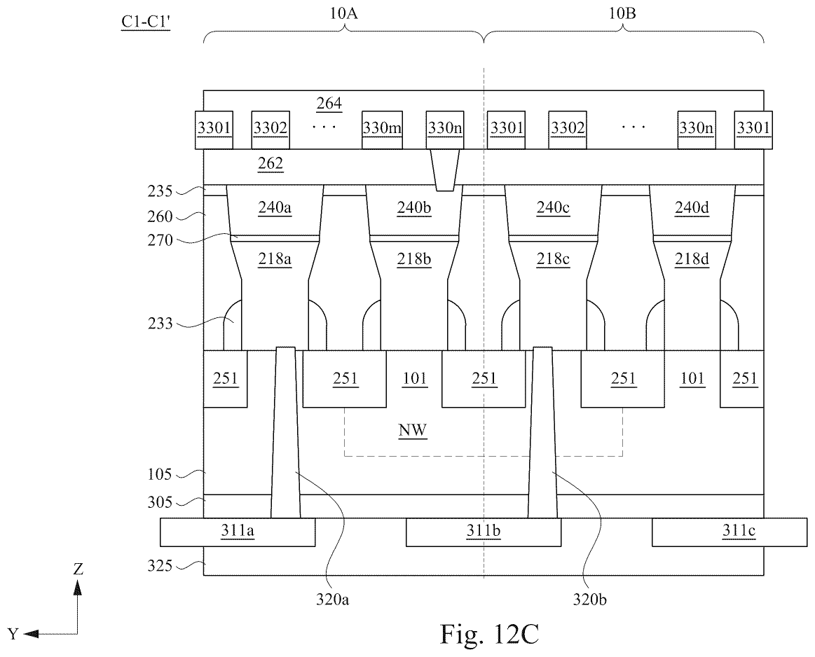

Reference is made to FIGS. 12A through 12C. FIGS. 12A and 12B illustrate a layout diagram of a logic circuit 110 on a backside and a front-side of a semiconductor structure, respectively, according to some embodiments of the present disclosure. FIG. 12C illustrates a cross-sectional view obtained from reference cross-sections C1-C1′ in FIGS. 12A and 12B.

A difference between the structure as illustrated in FIGS. 2A through 2E and the structure as illustrated in FIGS. 12A through 12C includes that the source/drain regions 218a, 218b and 218c extend to the nearest cell boundaries along the Y-direction, and the metal lines 3301 are shift based on the extension of the source/drain regions 218a and 218c so that the metal lines 3301 are able to overlaps the source/drain regions 218a and 218c. In FIGS. 12B and 12C, the source/drain contact via 244 is electrically connected to the extending source/drain region 218b near the cell boundary. FIG. 12B further illustrates n numbers of the metal lines 3301, 3302, . . . 330m and 330n with the same width W1 non-overlap the cell boundaries presented as dash-lines.

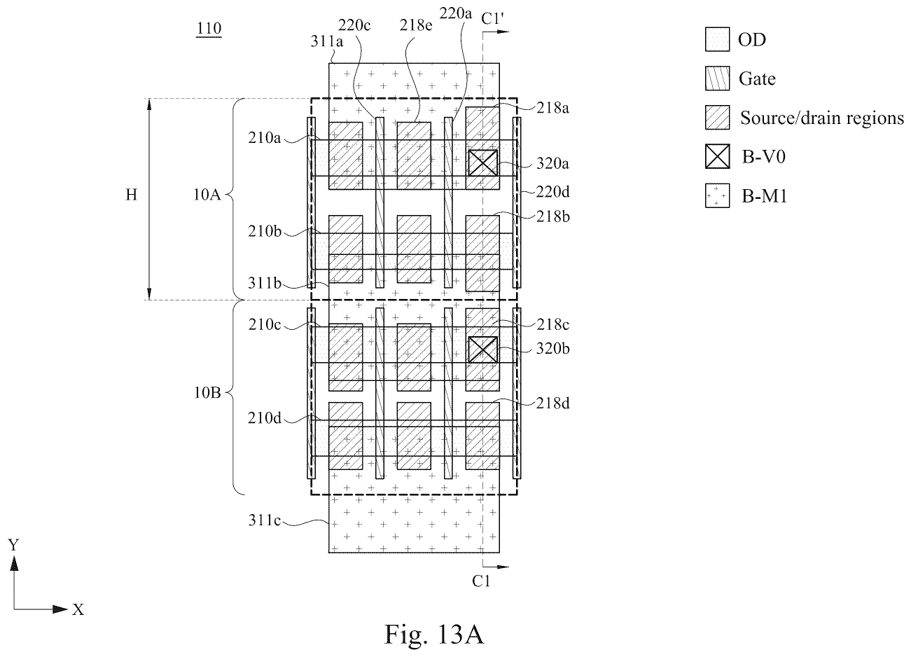

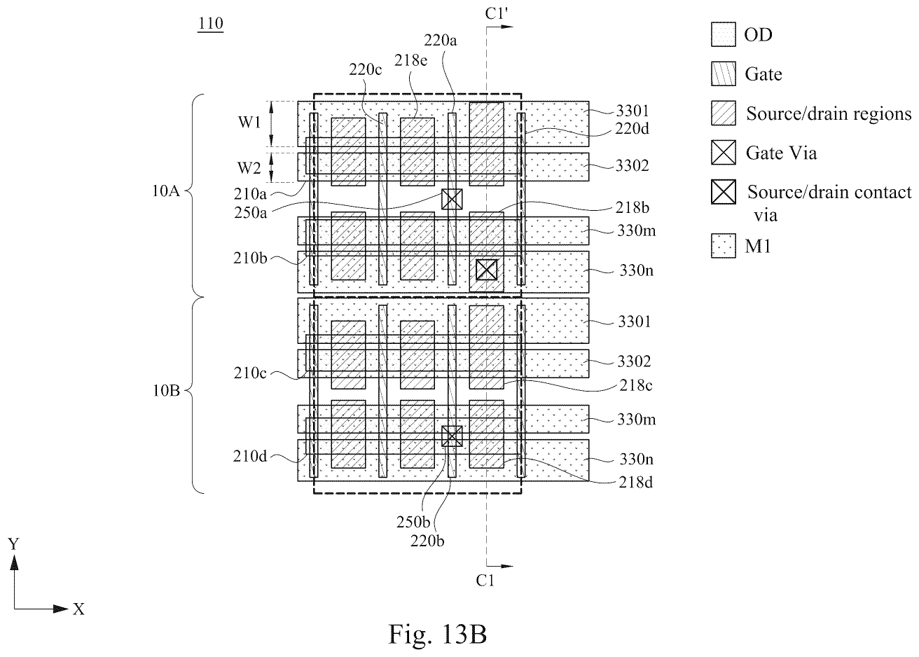

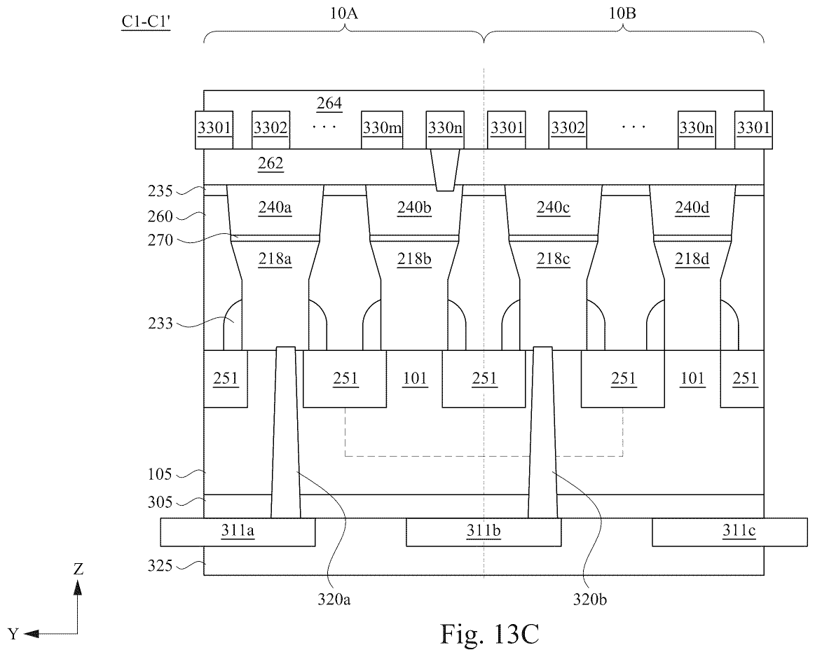

Reference is made to FIGS. 13A through 13C. FIGS. 13A and 13B illustrate a layout diagram of a logic circuit 110 on a backside and a front-side of a semiconductor structure, respectively, according to some embodiments of the present disclosure. FIG. 13C illustrates a cross-sectional view obtained from reference cross-sections C1-C1′ in FIGS. 13A and 13B.

A difference between the structure as illustrated in FIGS. 2A through 2E and the structure as illustrated in FIGS. 13A through 13C includes in FIGS. 13B and 13C the front-side metal lines 330 may have different widths. For example, as illustrated in FIG. 13B, in the cell 10A the metal line 3301 has a width W1, the metal line 3302 has a width W2, and the width W2 of the metal line 3302 is less than the width W1 of the metal line 3301. Furthermore, as illustrated in FIG. 13B, n numbers of the metal lines 3301, 3302, . . . 330m and 330n non-overlap the cell boundaries presented as dash-lines. In FIG. 13C, the source/drain contact via 244 may have a shift distance S1 from a side of the metal line 330n near the cell boundary and a shift distance S2 from a side of the metal line 330n away from the cell boundary. In some embodiments, the shift distance S1 is less than the shift distance S2.

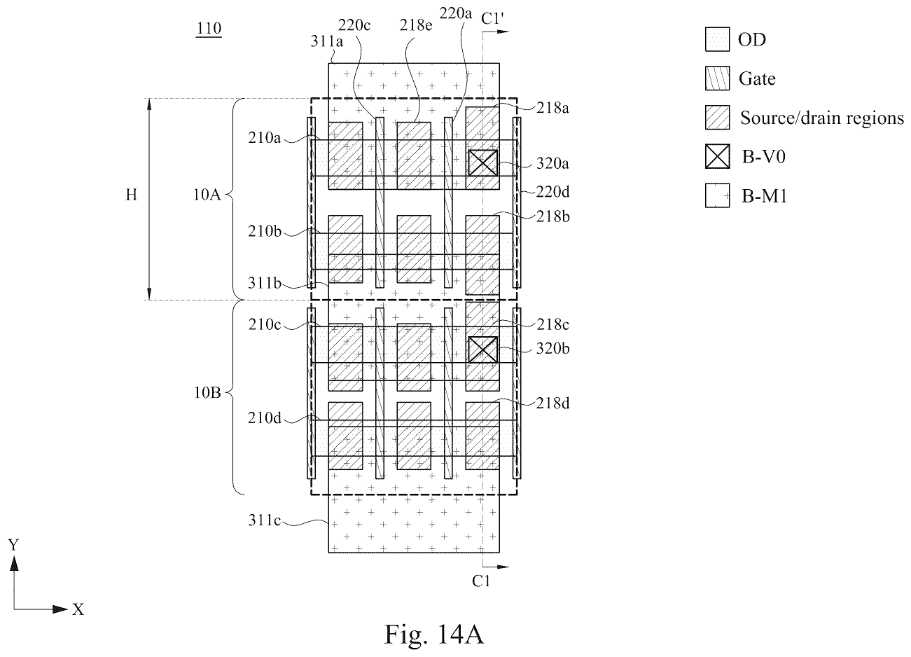

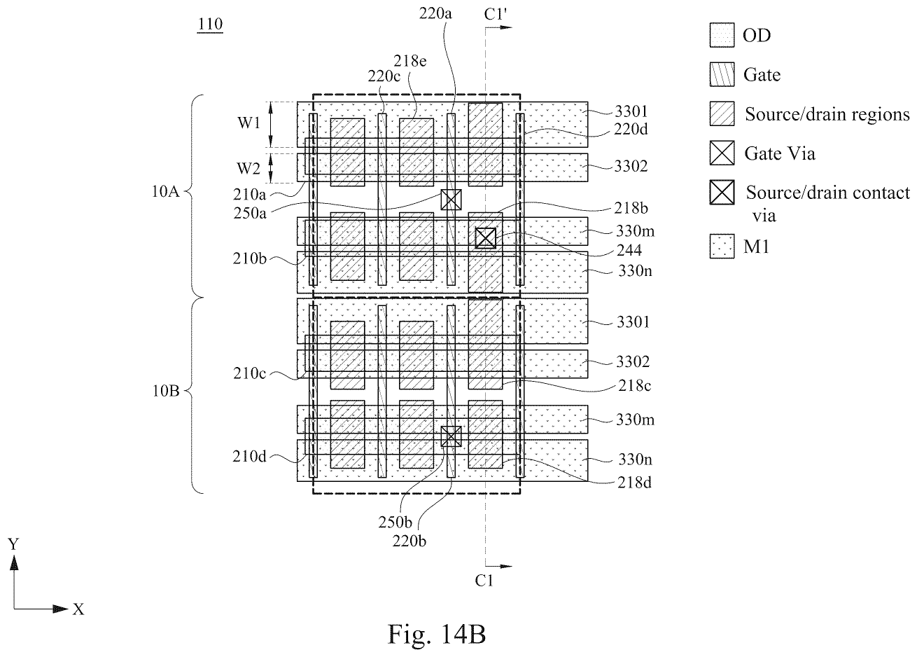

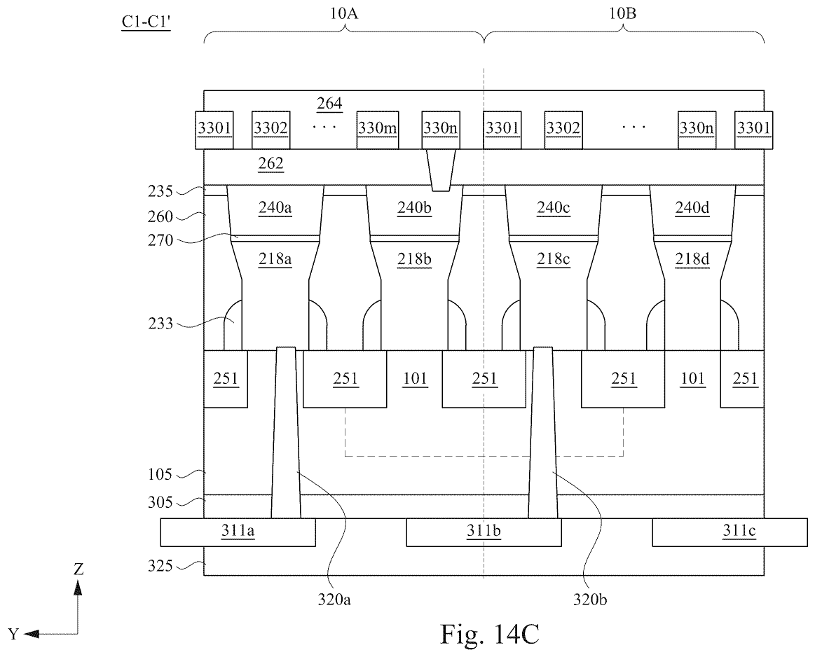

Reference is made to FIGS. 14A through 14C. FIGS. 14A and 14B illustrate a layout diagram of a logic circuit 110 on a backside and a front-side of a semiconductor structure, respectively, according to some embodiments of the present disclosure. FIG. 14C illustrates a cross-sectional view obtained from reference cross-sections C1-C1′ in FIGS. 14A and 14B.

A difference between the structure as illustrated in FIGS. 13A through 13C and the structure as illustrated in FIGS. 14A through 14C includes that as illustrated in FIGS. 14B and 14C, the source/drain contact via 244 may have a shift distance S1 from a side of the metal line 330n near the cell boundary and a shift distance S2 from a side of the metal line 330n away from the cell boundary, and the shift distance S1 is greater than the shift distance S2.

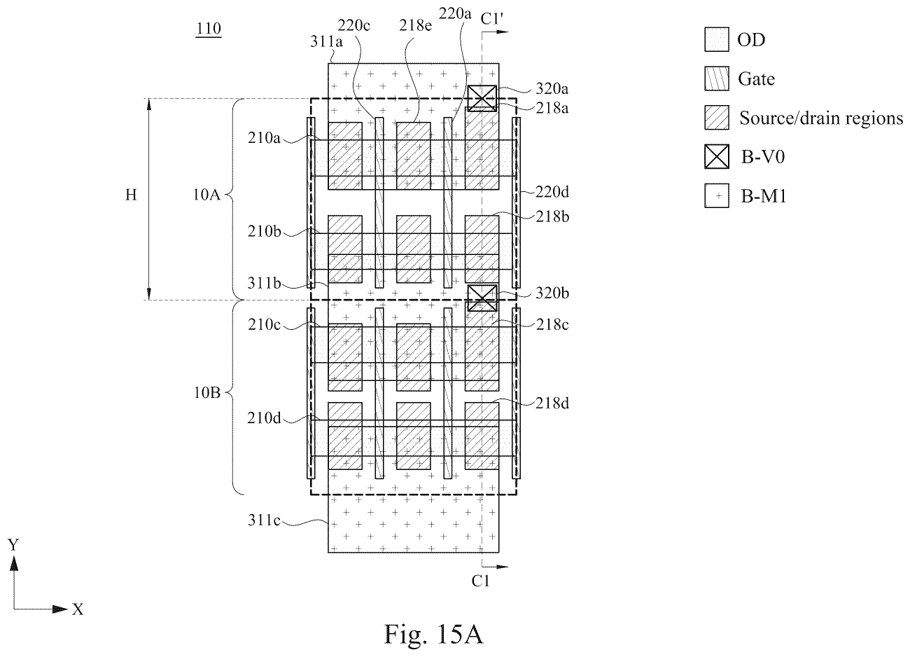

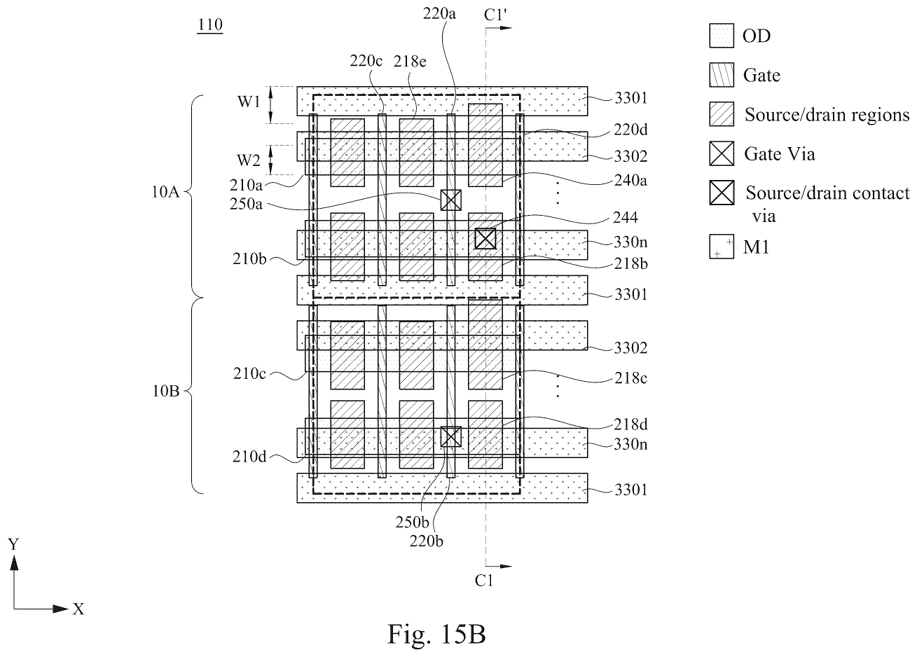

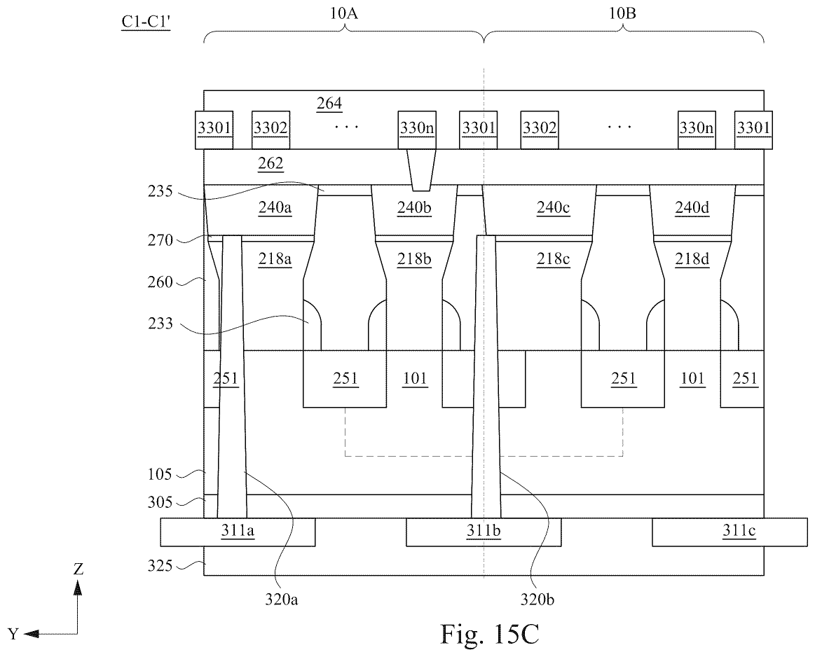

Reference is made to FIGS. 15A through 15C. FIGS. 15A and 15B illustrate a layout diagram of a logic circuit 110 on a backside and a front-side of a semiconductor structure, respectively, according to some embodiments of the present disclosure. FIG. 15C illustrates a cross-sectional view obtained from reference cross-sections C1-C1′ in FIGS. 15A and 15B.

A difference between the structure as illustrated in FIGS. 2A through 2E and the structure as illustrated in FIGS. 15A through 15C includes that as illustrated in FIGS. 15A and 15C, the backside contacts 320a and 320b are respectively at center regions of the backside metallization layers 311a and 311b. As illustrated in FIG. 15C, the backside contacts 320a and 320b are closed to or over the cell boundaries of the cells 10A and 10B. The source/drain regions 240a and 240c are extended to the nearest cell boundaries of the cells 10A and 10B. In FIG. 15C, the backside contacts 320a and 320b respectively extend through the source/drain regions 240a and 240c to the corresponding silicide regions 270. On the other hands, the backside contacts 320a and 320b as illustrated in FIG. 15C may be regarded as hole-like backside contacts in contact with sidewalls of the source/drain regions 240a and 240c. In some embodiments, the backside contacts 320a and 320b may extend through the gate spacers 233.

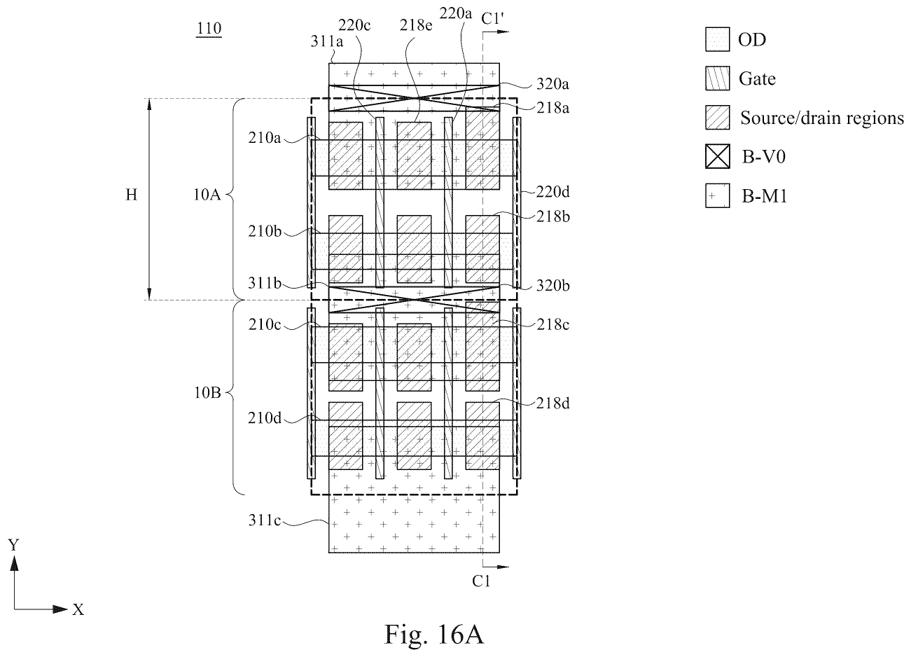

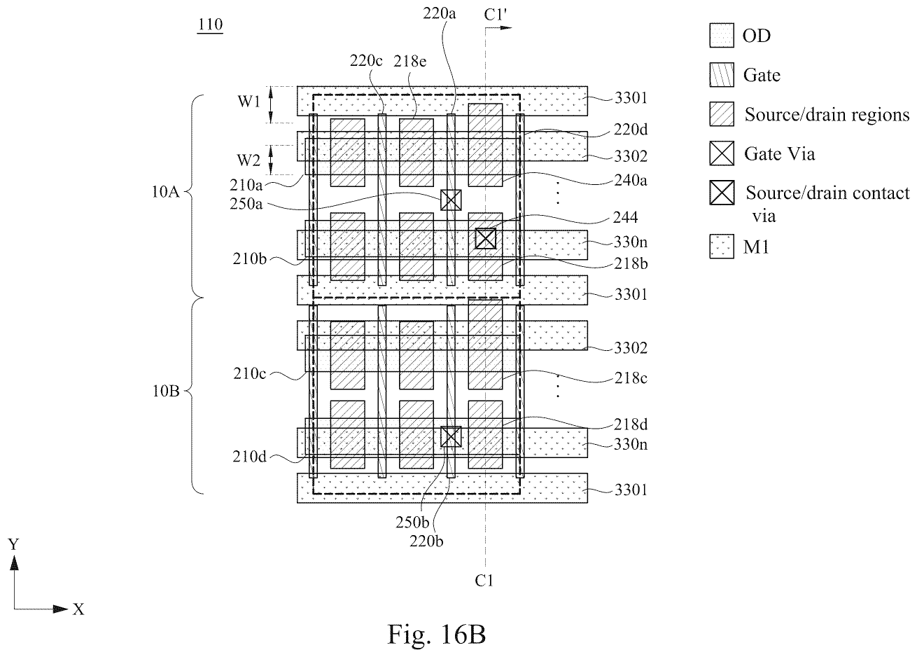

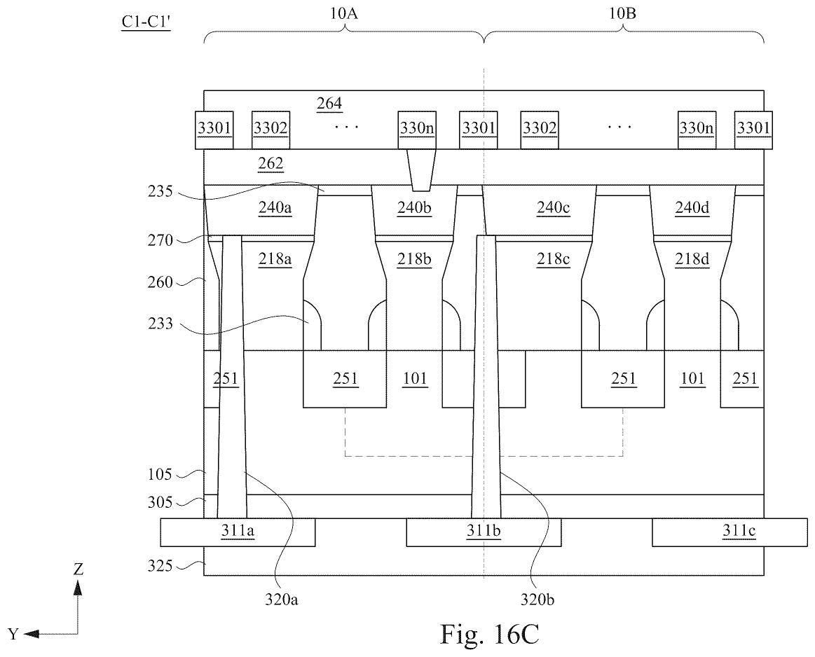

Reference is made to FIGS. 16A through 16C. FIGS. 16A and 16B illustrate a layout diagram of a logic circuit 110 on a backside and a front-side of a semiconductor structure, respectively, according to some embodiments of the present disclosure. FIG. 16C illustrates a cross-sectional view obtained from reference cross-sections C1-C1′ in FIGS. 16A and 16B.

A difference between the structure as illustrated in FIGS. 15A through 15C and the structure as illustrated in FIGS. 16A through 16C includes that as illustrated in FIGS. 16A and 16C, the backside contacts 320a and 320b extend along the X-direction to overlap the cell boundaries of the cells 10A and 10B. On the other hands, the backside contacts 320a and 320b as illustrated in FIG. 15C may be regarded as trench-like backside vias on sidewalls of the source/drain regions 240a and 240c.

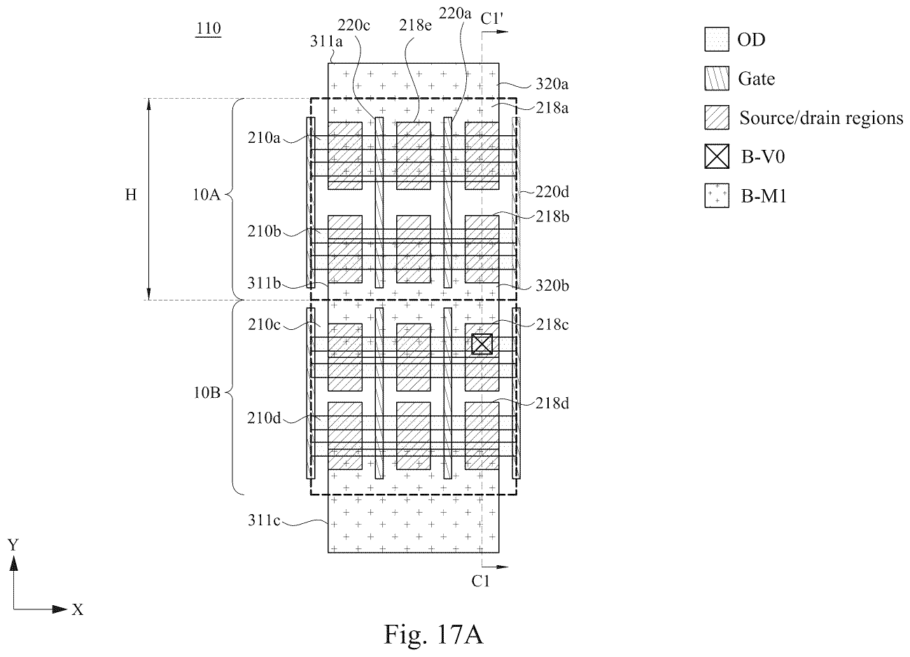

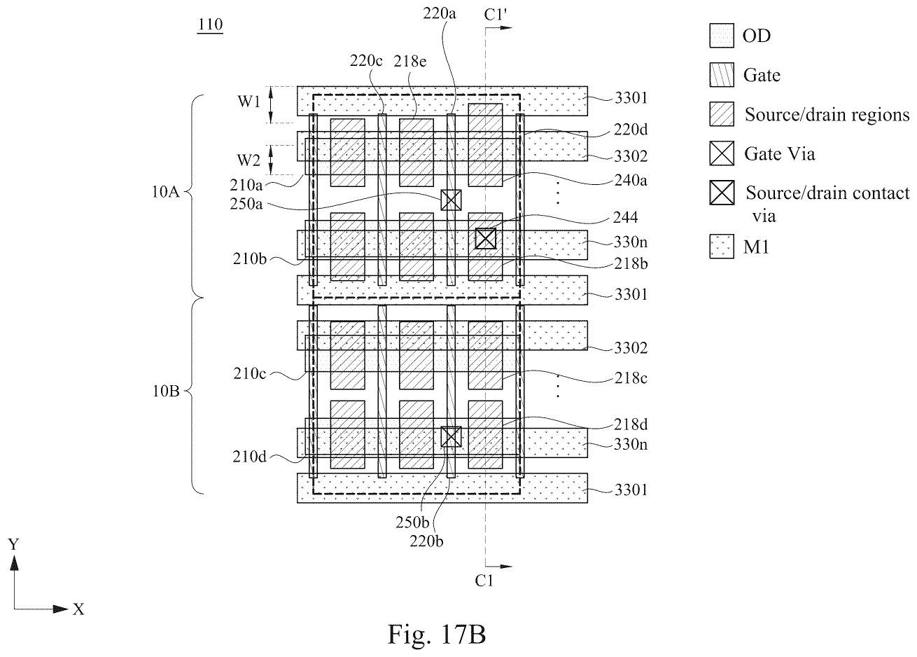

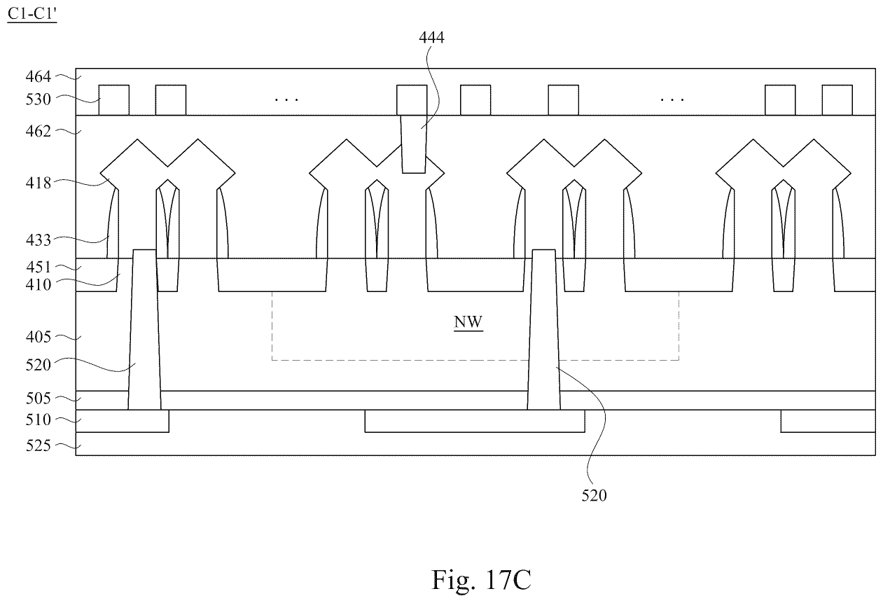

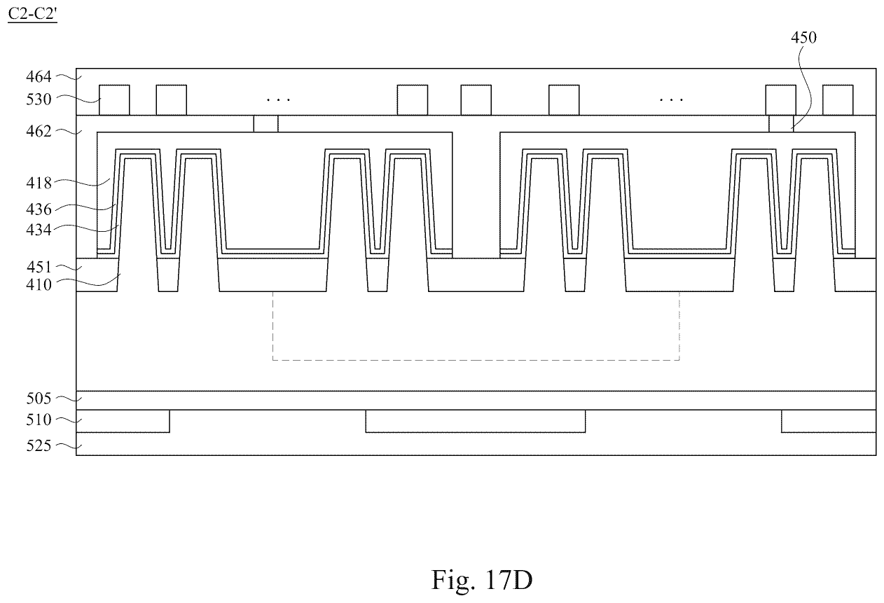

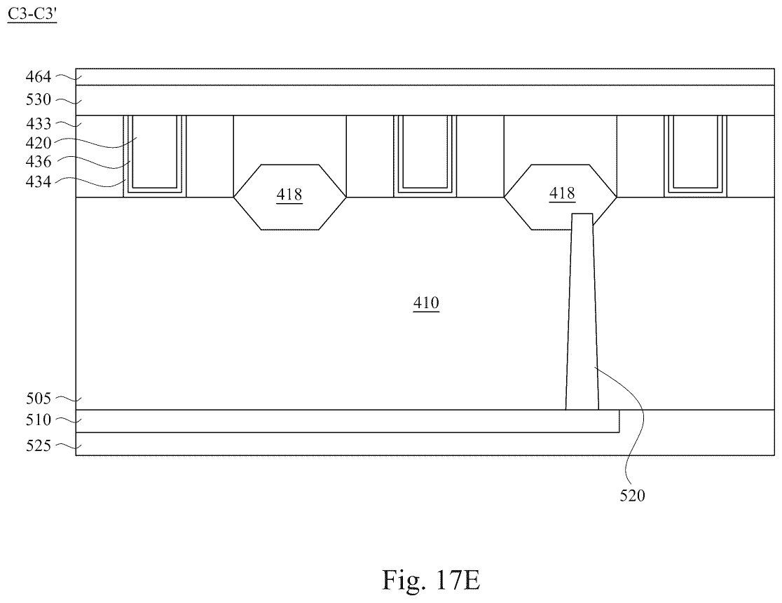

Reference is made to FIGS. 17A through 17E. FIGS. 17A and 17B illustrate a layout diagram of a logic circuit 110 on a front-side and a backside of a semiconductor structure, respectively, according to some embodiments of the present disclosure. FIGS. 17C, 17D and 17E illustrate cross-sectional views obtained from reference cross-sections C1-C1′, C2-C2′ and C3-C3′ in FIGS. 17A and 17B. In one or more embodiments of the present disclosure, the logic circuit 110 may include a plurality of FinFETs.

In FIGS. 17A and 17B, the logic circuit 110 may include a plurality of semiconductor fins 410 extending along the X-direction. Gate electrodes 420 are formed over the semiconductor fins 410 and extend along the Y-direction. Source/drain regions 418 are formed on opposite sides of the gate electrodes 420. In some embodiments, each of the source/drain regions 418 extending two immediately-adjacent semiconductor fins 410 and can be regarded as common source/drain regions 418. In FIG. 17A, a plurality of metallization layers 511 are formed along the X-direction and below the semiconductor fins 410 and the metallization layers 511 may be electrically connected to the source/drain regions 418 through backside contacts 520. In FIG. 17B, a plurality of metal lines 530 extend along the X-direction and overlap the semiconductor fins 410. The metal lines 530 may be electrically connected to the gate electrodes 420 through gate vias 450. The metal lines 530 may be electrically connected to the source/drain regions 418 through source/drain contact vias 444.

In one or more embodiments of the present disclosure, the metallization layers 511 may include a power supply voltage line interchangeably referred to as a Vdd line that is provided with positive a power supply voltage Vdd, and a power supply voltage line interchangeably referred to as a Vss line that is provided with power supply voltage Vss. In some embodiments, the cell can be powered through the positive power supply node Vdd that has a positive power supply voltage (also denoted as VDD). The cell can be also connected to power supply voltage Vss (also denoted as VSS), which may be an electrical ground. In some embodiments, the cell can be powered through the positive power supply node Vdd that has a positive power supply voltage (also denoted as VDD). The cell can be also connected to power supply voltage Vss (also denoted as VSS), which may be an electrical ground. Throughout the description, the notations of metal lines may be followed by the metal line levels they are in, wherein the respective metal line level is placed in parenthesis. The metallization layers 511 of the logic circuit 110 on the backside of the semiconductor structure may be used as backside power rails (BSPRs) for the logic circuit 110.

In one or more embodiments of the present disclosure, the metal lines 530 of the logic circuit 110 on the front-side of the semiconductor structure may be used for signal routing and not for power, and the logic circuit 110 is powered only by the metallization layers 511 of the logic circuit 110 on the backside of the semiconductor structure, so as to reduce cell height occupied by front-side power rail in the chip area and/or boost circuit performance. It should be noted that the configuration of the logic circuit 110 as illustrated in FIGS. 17A through 17E are used as an illustration, and not to limit the disclosure. For illustration, the front-side gate vias 450, the front-side source/drain via 444 and the backside contacts 520 near the reference cross-sections C1-C1′, C2-C2′ and C3-C3′ are illustrated. In some embodiments, numbers of front-side vias and backside contacts may be provided to connect the source/drain regions 418 and the gate electrodes 420 to the metallization layers 511 or the metal lines 530.

FIGS. 17C, 17D and 17E illustrate cross-sectional views obtained from reference cross-sections C1-C1′, C2-C2′ and C3-C3′ in FIGS. 17A and 17B.

As illustrated in FIGS. 17C, 17D and 17E, the logic circuit 110 may include semiconductor fins 404 over a substrate 405. A plurality of isolation structures 451 is formed between the semiconductor fins 404 over the substrate 405. In FIGS. 17C and 17D, portions of semiconductor fins 404 are over n-type well region NW may be used to form p-type transistors, and the semiconductor fins 404 out of the n-type well region NW may be used to form n-type transistors. The logic circuit 110 includes source/drain regions 418 over the fin 404 and gate structures including interfacial layers 434, high-k gate dielectric layers 436 over the interfacial layers 434 and the gate electrodes 420. The gate structure including interfacial layers 434, high-k gate dielectric layers 436 over the interfacial layers 434 and the gate electrodes 420 may be formed between the gate spacers 433. An ILD layer 462 is formed over the gate electrode 420 and the source/drain regions 418. Front-side vias including the source/drain contact via 444 and the gate via 450 are formed within the ILD layer 462. An IMD layer 464 is formed over the ILD layer 462 and a plurality of metal lines 530 are formed within the IMD layer 464. The IMD layer 464 and the metal lines 530 may be regarded as front-side interconnect structure.

After the front-side interconnect structure is formed, the substrate 405 may be “flipped” upside down so that the backside of the substrate 405 faces up. An ILD layer 505 may be formed over the backside of the substrate 405. Backside contacts 520 are formed and extend through the ILD 505 and the substrate 405 to the source/drain region 418. A backside interconnect structure including a backside IMD layer 525 and the backside metallization layers 510 within the IMD layer 525 are subsequently formed over the ILD layer 505. After the backside interconnect structure is formed, the substrate 405 may be “flipped” upside down again so that the backside of the substrate 105 faces down, and the semiconductor structure as illustrated in FIGS. 17A through 17E is formed.

As illustrated in FIGS. 17A through 17E, in one or more embodiments of the present disclosure, each of the source/drain regions 418 is connected to at most one of the metal lines 530 of the logic circuit 110 on the front-side of the semiconductor structure and the metallization layers 411 of the logic circuit 110 on the backside of the semiconductor structure.

The source/drain region 418 connected to the front-side source/drain contact via 444 is free of the backside source/drain contacts 520, and the source/drain region 418 connected to the back-side source/drain contacts 520 is free of the front-side source/drain contact via 444. An entirety of a front-side of the source/drain region 418 is covered by the ILD layer 462. Therefore, it either reduces cell height occupied by front-side power rail in the chip area or boosts circuit performance by enlarging front-side signal metal width/space.

According to one or more embodiments of the present disclosure, a method of forming a semiconductor structure includes a number of operations. Source/drain regions are formed on opposite sides of channel regions over a substrate. A gate structure is formed over the channel regions. A plurality of metal lines is formed over a front-side of the substrate. A plurality of metallization layers is formed on a backside of the substrate. A backside source/drain contact is formed on a second one of the source/drain regions, wherein the second one of the source/drain regions is free of a front-side source/drain contact. In one or more embodiments of the present disclosure, the metal lines over the front-side of the substrate have different widths. In one or more embodiments of the present disclosure, the channel regions include a plurality of semiconductor fins. In one or more embodiments of the present disclosure, the channel regions include semiconductor sheets. In one or more embodiments of the present disclosure, the backside source/drain contact is in contact with a sidewall of the second one of the source/drain regions. In one or more embodiments of the present disclosure, the backside source/drain contact extends to a top surface the second one of the source/drain regions. In one or more embodiments of the present disclosure, the backside source/drain contact is formed on a center region of one of the metallization layers. In one or more embodiments of the present disclosure, the method further includes forming a front-side gate via on a gate electrode of the gate structure. In one or more embodiments of the present disclosure, the method further includes forming a dielectric material over the source/drain regions, wherein a front-side surface of the second one of the source/drain regions is entirety covered by the dielectric material.

According to one or more embodiments of the present disclosure, a method of forming a semiconductor structure includes a number of operations. A plurality of transistors is formed over a substrate. A dielectric material is formed over the transistors. A front-side source/drain contact is formed on a first one of source/drain regions of the transistors. A backside source/drain contact is formed on a second one of the source/drain regions of the transistors, wherein a front-side surface of the second one of the source/drain regions is entirety covered by the dielectric material. In one or more embodiments of the present disclosure, the transistors are comprised in a first cell and a second cell, and the front-side source/drain contact overlaps a cell boundary of the first and second cells. In one or more embodiments of the present disclosure, the transistors are comprised in a first cell and a second cell, and the backside source/drain contact is formed on a cell boundary of the first and second cells. In some embodiments, the backside source/drain contact extends along the cell boundary of the first and second cells. In one or more embodiments of the present disclosure, the method further includes forming a plurality of metal lines over the dielectric material, wherein the front-side source/drain contact connects one of the metal line and the first one of the source/drain regions. In one or more embodiments of the present disclosure, the method further includes forming a plurality of metallization layers below the backside of the substrate, wherein the backside source/drain contact connects one of the metallization layers and the second one of the source/drain regions.

According to one or more embodiments of the present disclosure, a semiconductor structure includes a substrate, a first transistor, a second transistor, an isolation layer and a backside conductive feature. The first transistor is in a first active region over the substrate. The second transistor is in a second active region over the substrate. The first and second transistors include a gate structure couples first channel layers of the first transistor and second channel layers of second transistor. The isolation layer intervenes between the first and second active regions. The backside conductive feature is coupled to the first transistor. The first transistor is free of a front-side interconnect structure. In one or more embodiments of the present disclosure, the semiconductor structure further includes a backside contact connecting a source/drain region of the first transistor and the backside conductive feature. In some embodiments, the backside contact extends through the substrate and into the source/drain region of the first transistor. In one or more embodiments of the present disclosure, the semiconductor structure further includes a front-side conductive feature. The front-side interconnect structure connects the front-side conductive feature to a source/drain region of the second transistor. In one or more embodiments of the present disclosure, the semiconductor structure further includes a dielectric layer over a source/drain region of the first transistor. A front-side surface of the source/drain region of the first transistor is entirety covered by the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming source/drain regions on opposite sides of channel regions over a substrate;
forming a gate structure over the channel regions;
forming a plurality of metal lines over a front-side of the substrate;
forming a plurality of metallization layers on a backside of the substrate;
forming a front-side source/drain contact on a first one of the source/drain regions; and
forming a backside source/drain contact on a second one of the source/drain regions, wherein the second one of the source/drain regions is free of a front-side source/drain contact.

2. The method of claim 1, wherein the metal lines over the front-side of the substrate have different widths.

3. The method of claim 1, wherein the channel regions comprise a plurality of semiconductor fins.

4. The method of claim 1, wherein the channel regions comprise semiconductor sheets.

5. The method of claim 1, wherein the backside source/drain contact is in contact with a sidewall of the second one of the source/drain regions.

6. The method of claim 1, wherein the backside source/drain contact extends to a top surface the second one of the source/drain regions.

7. The method of claim 1, wherein the backside source/drain contact is formed on a center region of one of the metallization layers.

8. The method of claim 1, further comprising:
forming a front-side gate via on a gate electrode of the gate structure.

9. The method of claim 1, further comprising:
forming a dielectric material over the source/drain regions, wherein a front-side surface of the second one of the source/drain regions is entirety covered by the dielectric material.

10. A method, comprising:
forming a plurality of transistors over a substrate;
forming a dielectric material over the transistors;
forming a front-side source/drain contact on a first one of source/drain regions of the transistors;
forming a backside source/drain contact on a second one of the source/drain regions of the transistors, wherein a front-side surface of the second one of the source/drain regions is entirety covered by the dielectric material.

11. The method of claim 10, wherein the transistors are comprised in a first cell and a second cell, and the front-side source/drain contact overlaps a cell boundary of the first and second cells.

12. The method of claim 10, wherein the transistors are comprised in a first cell and a second cell, and the backside source/drain contact is formed on a cell boundary of the first and second cells.

13. The method of claim 12, wherein the backside source/drain contact extends along the cell boundary of the first and second cells.

14. The method of claim 10, further comprising:
forming a plurality of metal lines over the dielectric material, wherein the front-side source/drain contact connects one of the metal line and the first one of the source/drain regions.

15. The method of claim 10, further comprising:
forming a plurality of metallization layers below the backside of the substrate, wherein the backside source/drain contact connects one of the metallization layers and the second one of the source/drain regions.

16. A semiconductor structure, comprising:
a substrate;
a first transistor in a first active region over the substrate;
a second transistor in a second active region over the substrate, wherein the first and second transistors comprise a gate structure couples first channel layers of the first transistor and second channel layers of second transistor;
an isolation layer intervening between the first and second active regions; and
a backside conductive feature coupled to the first transistor, wherein the first transistor is free of a front-side interconnect structure.

17. The semiconductor structure of claim 16, further comprising:
a backside contact connecting a source/drain region of the first transistor and the backside conductive feature.

18. The semiconductor structure of claim 17, wherein the backside contact extends through the substrate and into the source/drain region of the first transistor.

19. The semiconductor structure of claim 16, further comprising:
a front-side conductive feature, wherein the front-side interconnect structure connects the front-side conductive feature to a source/drain region of the second transistor.

20. The semiconductor structure of claim 16, further comprising:
a dielectric layer over a source/drain region of the first transistor, wherein a front-side surface of the source/drain region of the first transistor is entirety covered by the dielectric layer.
